(19) United States
(12) Patent Application Publication
(10) Pub. No.: US 2014/0311566 A1
(43) Pub. Date: Oct. 23, 2014

(54) MICROSTRUCTURED WAVELENGTH CONVERSION FILMS FOR ENHANCED SOLAR HARVESTING EFFICIENCY

(71) Applicant: NITTO DENKO CORPORATION, OSAKA (JP)

(72) Inventors: Hongxi Zhang, Temecula, CA (US); Peng Wang, San Diego, CA (US); Stanislaw Rachwal, Oceanside, CA (US); Zongcheng Jiang, Oceanside, CA (US); Michiharu Yamamoto, Carlsbad, CA (US)

(21) Appl. No.: 14/355,833

(22) PCT Filed: Nov. 2, 2012
(86) PCT No.: PCT/US2012/063218

§ 371 Date: May 1, 2014

Related U.S. Application Data
(60) Provisional application No. 61/555,799, filed on Nov. 4, 2011.

(51) Int. Cl. H01L 31/0232; H01L 31/055; G02B 5/20

(52) U.S. Cl. CPC H01L 31/02322; G02B 5/206; H01L 31/055
USPC 136/257; 136/252; 438/71

(57) ABSTRACT

Described herein are microstructured wavelength conversion films for enhanced solar harvesting efficiency of photovoltaic devices or solar cells. The microstructured wavelength conversion film comprises a luminescent medium that is provided with a microstructured surface, where the luminescent medium and the microstructured surface can be combined into a single layer or made up of two or more separate layers. A photovoltaic module which utilizes the medium to improve the performance of photovoltaic devices or solar cells is also provided, along with a method of improving a solar cell or photovoltaic device by utilizing the microstructured wavelength conversion film.

### CROSS-REFERENCE TO RELATED APPLICATIONS

This application claims priority to U.S. Provisional Patent Application No. 61/555,799, filed on Nov. 4, 2011, the content of which is hereby incorporated by reference in its entirety.

### BACKGROUND OF THE INVENTION

1. Field of the Invention

The present invention generally relates to wavelength conversion films having microstructured surfaces for enhanced solar harvesting efficiency of solar energy conversion devices or solar cells.

2. Description of the Related Art

The utilization of solar energy offers a promising alternative energy source to the traditional fossil fuels, and therefore, the development of solar energy conversion devices that can convert solar energy into electricity, such as photovoltaic devices (also known as solar cells), has drawn significant attention in recent years. Several different types of mature photovoltaic devices have been developed, including a Silicon based device, a III-V and II-VI PN junction device, a Copper-Indium-Gallium-Selenium (CIGS) thin film device, an organic sensitizer device, an organic thin film device, and a Cadmium Sulfide/Cadmium Telluride (CdS/CdTe) thin film device, to name a few. However, the photoelectric conversion efficiency of many of these devices still has room for improvement and development of techniques to improve this efficiency has been an ongoing challenge for many researchers.

Recently, one technique developed to improve the efficiency of photovoltaic devices is to utilize a wavelength down-shifting film. Many of the photovoltaic devices are unable to effectively utilize the entire spectrum of light as the materials on the device absorb certain wavelengths of light (typically the shorter UV wavelengths) instead of allowing the light to pass through to the photoconductive material layer where it is converted into electricity. Application of a wavelength down-shifting film absorbs the shorter wavelength photons and re-emits them at more favorable longer wavelengths, which can then be absorbed by the photoconductive layer in the device, and converted into electricity.

This phenomenon is often observed in the thin film CdS/CdTe and CIGS solar cells which both use CdS as the window layer. The low cost and high efficiency of these thin film solar cells has drawn significant attention in recent years, with typical commercial cells having photoelectric conversion efficiencies of 10-16%. However, one issue with these devices is the energy gap of CdS, approximately 2.41 eV, which causes light at wavelengths below 514 nm to be absorbed by CdS instead of passing through to the photoconductive layer where it can be converted into energy. This inability to utilize the entire spectrum of light effectively reduces the overall photoelectric conversion efficiency of the device.

There have been numerous reports disclosing the utilization of a wavelength down-shifting material to improve the performance of photovoltaic devices. For example, U.S. Patent Application Publication No. 2009/0151785 discloses a silicon based solar cell which contains a wavelength down-shifting inorganic phosphor material. U.S. Patent Application Publication No. US 2011/0011455 discloses an integrated solar cell comprising a plasmonic layer, a wavelength conversion layer, and a photovoltaic layer. U.S. Pat. No. 7,791,157 discloses a solar cell with a wavelength conversion layer containing a quantum dot compound. U.S. Patent Application Publication No. 2010/0294339 discloses an integrated photovoltaic device containing a luminescent down-shifting material, however no example embodiments was constructed. U.S. Patent Application Publication No. 2010/0012183 discloses a thin film solar cell with a wavelength down-shifting photo-luminescent medium; however, no examples are provided. Each of these patents and patent application publications, which are incorporated herein by reference in their entirety, promote the use of an inorganic material to enable the wavelength down-shifting. However, in U.S. Provisional Patent Application Nos. 61/430,053 and 61/485,093, the contents of which are incorporated by reference, the inventors disclosed a perylene diester derivative, which can be used to synthesize an organic photo-luminescent dye and then be incorporated into an optically transparent polymer matrix to form a wavelength conversion organic photo-luminescent medium with good photostability, greater than 5000 hours under one sun irradiation (AM1.5G). Additionally, this organic photo-luminescent medium was also found to enhance the photoelectric conversion efficiency of the thin film CIGS and CdS/CdTe solar cells by greater than 12% for CIGS cells, and greater than 15% for CdS/CdTe cells, when applied directly on the light incident surface of the device.

Although applying a wavelength conversion film to a photovoltaic device can broaden the spectrum of light that can be effectively converted into electricity by the photovoltaic device, the inventors have discovered that such film application can introduce additional inefficiencies. That is, the photons, once absorbed by the luminescent dye within the luminescent film and re-emitted at longer wavelengths, are often reflected out of the solar cell through the front or side surfaces of the film, instead of being transmitted into the more desirable photoelectrode layer. Therefore, further improvement in the solar energy conversion efficiency may be made through reducing the loss of the re-emitted photons to the environment.

### SUMMARY OF THE INVENTION

It was recently discovered that the use of a microstructured surface, in conjunction with a luminescent medium, acts to reduce the escaping loss of photons by increasing the total internal reflection and creating multiple reflection and refraction pathways which transmit more photons into the photoelectrode layer. This significantly enhances the photoelectric conversion efficiency of the photovoltaic device. Thus, a primary objective of the present invention is to provide a microstructured wavelength conversion film. By employing the film, a new type of optical light collection system, fluorescence-based solar collectors, fluorescence-activated displays, and single-molecule spectroscopy can be provided.

Some embodiments provide a microstructured wavelength conversion film comprising a bottom surface, a top surface for receiving incident light, wherein the top surface comprises structures configured to increase the amount of photos emitted through the bottom surface, and a luminescent medium layer comprising a first optically transparent polymer matrix and at least one luminescent dye. In some embodiments, the microstructured wavelength conversion film further comprises a microstructured polymer layer over the luminescent medium layer, wherein the microstructured polymer layer comprises a second optically transparent polymer matrix.

Some embodiments provide a solar energy conversion module comprising a solar cell and a microstructured wavelength conversion film as disclosed herein.

Some embodiments provide a method for improving the performance of a solar energy conversion device comprising applying a microstructured wavelength conversion film as disclosed herein onto a light incident surface for a solar cell.

Some embodiments provide a method for improving the performance of a solar energy conversion device comprising incorporating a microstructured wavelength conversion film disclosed herein into the solar energy conversion device, such that the luminescent medium layer is between a solar cell and a light incident surface for the solar cell.

### BRIEF DESCRIPTION OF THE DRAWINGS

FIG. 1 illustrates a solar cell having a wavelength conversion film applied thereon wherein photons are absorbed by a chromophore and re-emitted at a different wavelength.

FIG. 2 illustrates an embodiment of a microstructured wavelength conversion film.

FIG. 3 illustrates another embodiment of a microstructured wavelength conversion film.

FIG. 4 illustrates another embodiment of a microstructured wavelength conversion film.

FIG. 5 illustrates an embodiment of a photovoltaic device or solar cell in which a microstructured wavelength conversion film is directly attached to the light incident surface of the device.

FIG. 6 illustrates an embodiment of a photovoltaic device or solar cell in which a microstructured wavelength conversion film is fabricated directly into the module as an encapsulation layer.

FIG. 7 illustrates an embodiment of a photovoltaic device or solar cell in which a microstructured polymer layer and a luminescent medium layer are directly attached to the light incident surface of the device.

FIG. 8 illustrates another embodiment of a photovoltaic device or solar cell in which a microstructured polymer layer and a luminescent medium layer are directly attached to the light incident surface of the device.

FIG. 9 illustrates an embodiment of a photovoltaic device or solar cell in which a microstructured polymer layer and a luminescent medium layer are fabricated directly into the module as an encapsulation layer.

FIG. 10 illustrates another embodiment of a photovoltaic device or solar cell module in which a microstructured polymer layer and a luminescent medium are fabricated directly into the module as an encapsulation layer.

FIG. 11 illustrates an embodiment of a photovoltaic device or solar cell in which a microstructured polymer layer is directly attached to the light incident surface of the device.

### DETAILED DESCRIPTION OF THE PREFERRED EMBODIMENT

The embodiments will be explained with respect to preferred embodiments which are not intended to limit the present invention. In the present disclosure where conditions and/or structures are not specified, the skilled artisan in the art can readily provide such conditions and/or structures, in view of the present disclosure, as a matter of routine experimentation.

The present disclosure relates to a microstructured wavelength conversion film, and a solar energy conversion module which utilizes the same, to enhance the solar energy conversion efficiency. The use of luminescent wavelength conversion materials to improve the efficiency of photovoltaic devices and solar cells has been disclosed in several publications, including U.S. Pat. No. 7,791,157, and U.S. Patent Application Publication Nos. 2009/0151785, 2010/0294339, 2010/0012183. The use of a down-shifting medium in these photovoltaic and solar cell devices, when applied to the light incident side of the device, causes the shorter wavelength light to become excited and re-emitted from the medium at a longer (higher) more favorable wavelength, which can then be utilized by the photovoltaic device or solar cell. However, all of the publications fail to recognize that the introduction of an additional medium in the photovoltaic device, while increasing the spectrum of light which can be utilized by the device, also increases the amount of photons which are lost to the environment due to the internal reflection and refraction in the added wavelength conversion layer.

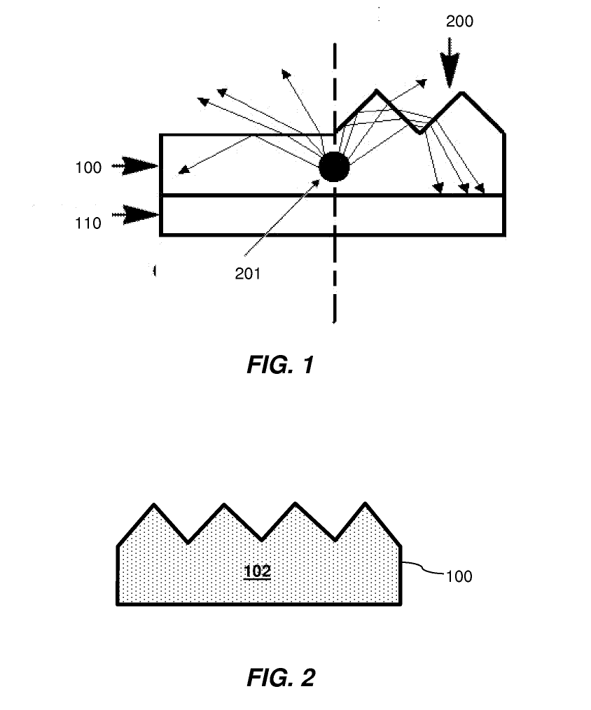

The inventors recently discovered that by using a luminescent wavelength conversion medium in combination with a microstructured light incident surface, the loss of photons to the environment is reduced as the microstructures act to redirect the photons into the photoelectrode layer of the solar cell to be converted into electricity. This further increases the efficiency of the photovoltaic devices. This phenomena is illustrated in FIG. 1, which shows a solar energy conversion device 110 having a wavelength conversion film 100 applied thereto. In the wavelength conversion film, photons are absorbed by the chromophore or luminescent dye 201 and re-emitted at a different wavelength. The dotted line shows a division between a plain, smooth surface (left) on the wavelength conversion film and a microstructured surface 200 (right) on the wavelength conversion film. As shown on the plain surface, many re-emitted photons are lost to the environment, as they exit the wavelength conversion film without entering the solar cell. On the other hand, the some of the re-emitted photons that contact or exit the microstructured surface are redirected back towards the solar cell by multiple reflection and refraction mechanisms. The microstructured wavelength conversion film is useful in various applications, such as optical light collection systems, fluorescence-based solar collectors, fluorescence-activated displays, and single-molecule spectroscopy, to name a few.

In some embodiments, the microstructured wavelength conversion film comprises a bottom surface and a top surface configured for receiving incident light or photons. The top surface is texturized, and has structures configured to increase the amount of photons emitted through the bottom surface. The luminescent medium layer comprises a first optically transparent polymer matrix and at least one luminescent dye. The luminescent medium layer receives as input at least one photon having a first wavelength, and provides as an output at least one photon having a second wavelength which is different than the first.

In some embodiments, the luminescent medium layer is the only layer in the microstructured wavelength conversion film. The microstructures or textures may be applied directly on the top surface of the layer. As illustrated in FIG. 2, the top surface of the luminescent medium layer 102 is therefore the top surface of the microstructured wavelength conversion film 100.

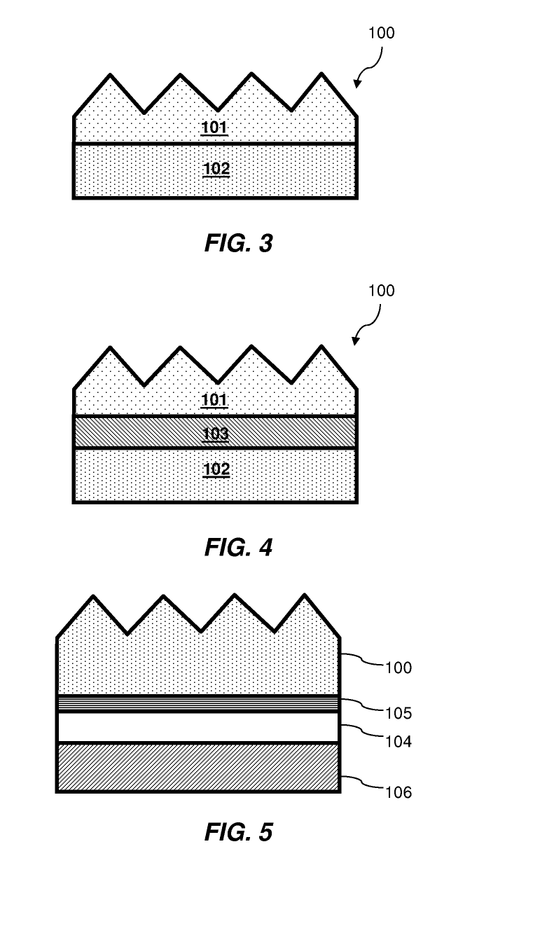

In some embodiments, the microstructured wavelength conversion film 100 can also comprise at least two separate layers, as illustrated in FIGS. 3 and 4. In these embodiments, the microstructured wavelength conversion film 100 comprises at least one luminescent medium layer 102 and a microstructured polymer layer 101. FIGS. 3 and 4 show that the microstructured polymer layer 101 is over the luminescent medium layer 102 such that incident light can first pass through the microstructured polymer layer 101. In FIG. 3, the luminescent medium layer 102 is below the microstructured polymer layer 101 such that the top surface of the luminescent medium layer 102 is in optical communication with the bottom surface of the microstructured polymer layer 101. In other words, the microstructured polymer layer 101 is on the luminescent medium layer 102. FIG. 4 shows that additional material layer(s) 103 can be present in between the luminescent medium layer 102 and the microstructured polymer layer 101. The microstructured polymer layer 101 comprises a second optically transparent polymer matrix, which may be the same or different than the first polymer matrix in the luminescent medium layer 102.

Some embodiments provide a solar energy conversion module for the conversion of solar light energy into electricity comprising at least one photovoltaic device or solar cell 106, and a microstructured wavelength conversion film 100 described herein. The microstructured wavelength conversion film 100 is incorporated on top of, or encapsulated into, a solar energy conversion device, such that the incident light passes through the microstructured wavelength conversion film prior to reaching the area of the module where the solar light energy is converted into electricity (e.g., solar cell 106).

The structures or the texture on the top surface of the microstructured wavelength conversion film can vary. In some embodiments of the inventions, the top surface is textured with structures independently selected from the group consisting of grooves, pyramids, prisms, cones, blocks, rings, pillars, and combinations thereof. The depth of the texturing can also vary. The peak to valley distance among the structures can be adjusted by using different molds or controlling the depth to which the mold is pressed into the polymer matrix. In some embodiments, the top surface is textured with structures having a peak to valley distance ranging from about 0.01 μm to about 100 μm. In some embodiments, the top surface is textured with structures having a peak to valley distance ranging from about 0.1 μm to about 75 μm. In some embodiments, the top surface is textured with structures having a peak to valley distance ranging from about 1 μm to about 50 μm. In some embodiments, the top surface is textured with structures having a peak to valley distance ranging from about 10 μm to about 30 μm.

The first transparent polymer matrix used in the luminescent medium layer and, if present, the second transparent polymer matrix for the microstructured polymer layer can vary and be independently selected. In some embodiments, the first or the second transparent polymer matrix comprises a substance selected from the group consisting of polyethylene terephthalate, polymethyl methacrylate, polyvinyl butyral, ethylene vinyl acetate, ethylene tetrafluoroethylene, polyimide, amorphous polycarbonate, polystyrene, siloxane sol-gel, polyurethane, polyacrylate, and combinations thereof. In some embodiments of the inventions, the refractive index of the first or the second polymer matrix material is in the range of about 1.4 to about 1.7. In some embodiments of the inventions, the refractive index of the first or the second polymer matrix material is in the range of about 1.45 to about 1.55.

In some embodiments, a microstructured wavelength conversion film 100 is a luminescent medium layer 102 which comprises a textured top surface as shown in FIG. 2 and at least one luminescent dye. The film can be fabricated by (i) preparing a polymer solution with dissolved polymer powder in tetrachloroethylene (TCE) at a predetermined ratio; (ii) preparing a luminescent dye containing a polymer mixture by mixing the polymer solution with the luminescent dye at a predetermined weight ratio to obtain a dye-containing polymer solution, (iii) forming the dye/polymer thin film by directly casting the dye-containing polymer solution onto a glass substrate, then heat treating the substrate from room temperature up to 100° C. in 2 hours, completely removing the remaining solvent by further vacuum heating at 130° C. overnight, and (iv) peeling off the dye/polymer thin film under the water and then drying out the free-standing polymer film before use; (v) the film thickness can be controlled from 0.1 μm˜1 mm by varying the dye/polymer solution concentration and evaporation speed; (vi) then forming the microstructures by embossing at elevated temperatures using a master film as a cast and hotpressing until the structures are formed on the surface.

In some embodiments, a microstructured wavelength conversion film 100, which comprises a microstructured polymer layer 101 with a textured top surface, and a luminescent medium layer 102 made of a first optically transparent polymer matrix and at least one luminescent dye, is fabricated into two separate thin films, as illustrated in FIGS. 3 and 4.

The luminescent medium layer 102 is fabricated into a plain wavelength conversion thin film structure by (i) preparing a polymer solution with dissolved polymer powder in TCE at a predetermined ratio; (ii) preparing a luminescent dye containing a polymer mixture by mixing the polymer solution with the luminescent dye at a predetermined weight ratio to obtain a dye-containing polymer solution, (iii) forming a dye/polymer thin film by directly casting the dye-containing polymer solution onto a glass substrate, then heat treating the substrate from room temperature up to 100° C. in 2 hours, completely removing the remaining solvent by further vacuum heating at 130° C. overnight, and (iv) peeling off the dye/polymer thin film under the water and then drying out the free-standing polymer film before use; (v) the film thickness can be controlled from 0.1 μm˜1 mm by varying the dye/polymer solution concentration and evaporation speed.

The microstructured polymer layer 101 is fabricated using the same method as that used to fabricate the luminescent medium layer 102, except that the luminescent dye is not used. Once the polymer film is formed, the microstructures are fabricated by embossing at elevated temperatures. A master film is used as a cast and hotpressed against the film until the microstructures are formed on the surface.

In some embodiments, a commercial prismatic master film with grooves is used as the cast to emboss the microstructures into the polymer matrix. For example, the master film can be a Brightness Enhancement Film, Model No. BEF2, manufactured by 3M Ltd. Such a master film with grooves can provide the top surface with a textured structure of grooves. For example, the master film can have prism grooves with an angle of 90° and a depth ranging from about 10 μm to about 30 μm. As discussed above, the depth of the microstructures into the film may vary over a wide range depending on the embossing techniques and the thickness of the film. In some embodiments, grooves are directly embossed. The top surface can also be textured with pyramids utilizing a second embossing with the same grooves, and the second embossing being right-crossed with those of the first. Other structures can be achieved by selecting different master films for the embossing.

Various types of luminescent dyes can be included in the luminescent medium layer. In some embodiments of the inventions, the at least one luminescent dye is an organic dye. In some embodiments of the inventions, the at least one luminescent dye is selected from the group consisting of perylene derivative dyes, benzotriazole derivative dyes, and benzothiadiazole derivative dyes.

As used herein, an “electron donor group” is defined as any group which increases the electron density of the 2H-benzo[d][1,2,3]triazole system.

An “electron donor linker” is defined as any group that can link two 2H-benzo[d][1,2,3]triazole systems providing conjugation of their π orbitals, which can also increase or have neutral effect on the electron density of the 2H-benzo[d][1,2,3]triazole to which they are connected.

An “electron acceptor group” is defined as any group which decreases the electron density of the 2H-benzo[d][1,2,3]triazole system. The placement of an electron acceptor group at the N-2 position of the 2H-benzo[d][1,2,3]triazole ring system.

The term “alkyl” refers to a branched or straight fully saturated acyclic aliphatic hydrocarbon group (i.e. composed of carbon and hydrogen containing no double or triple bonds). Alkyls include, but are not limited to, methyl, ethyl, propyl, isopropyl, butyl, isobutyl, tertiary butyl, pentyl, hexyl, and the like.

The term “heteroalkyl” used herein refers to an alkyl group comprising one or more heteroatoms. When two or more heteroatoms are present, they may be the same or different.

The term “cycloalkyl” used herein refers to saturated aliphatic ring system radical having three to twenty carbon atoms including, but not limited to, cyclopropyl, cyclopentyl, cyclohexyl, cycloheptyl, and the like.

The term “alkenyl” used herein refers to a monovalent straight or branched chain radical of from two to twenty carbon atoms containing a carbon double bond including, but not limited to, 1-propenyl, 2-propenyl, 2-methyl-1-propenyl, 1-butenyl, 2-butenyl, and the like.

The term “alkynyl” used herein refers to a monovalent straight or branched chain radical of from two to twenty carbon atoms containing a carbon triple bond including, but not limited to, 1-propynyl, 1-butynyl, 2-butynyl, and the like.

The term “aryl” used herein refers to homocyclic aromatic radical whether one ring or multiple fused rings. Examples of aryl groups include, but are not limited to, phenyl, naphthyl, phenanthrenyl, naphthacenyl, fluorenyl, pyrenyl, and the like. Further examples include:

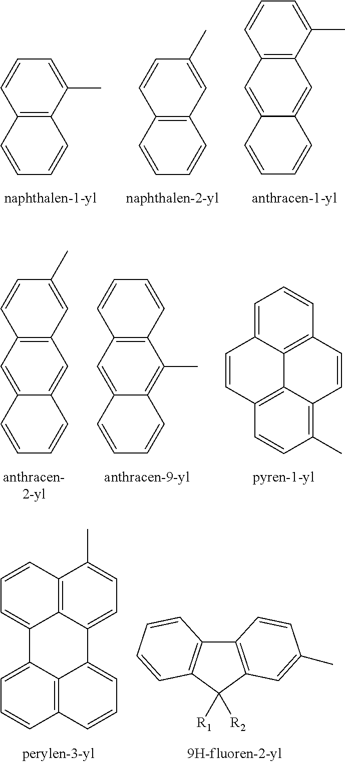

The term “alkaryl” or “alkylaryl” used herein refers to an alkyl-substituted aryl radical. Examples of alkaryl include, but are not limited to, ethylphenyl, 9,9-dihexyl-9H-fluorene, and the like.

The term “aralkyl” or “arylalkyl” used herein refers to an aryl-substituted alkyl radical. Examples of aralkyl include, but are not limited to, phenylpropyl, phenylethyl, and the like.

The term “heteroaryl” used herein refers to an aromatic ring system radical in which one or more ring atoms are heteroatoms, whether one ring or multiple fused rings. When two or more heteroatoms are present, they may be the same or different. In fused ring systems, the one or more heteroatoms may be present in only one of the rings. Examples of heteroaryl groups include, but are not limited to, benzothiazyl, benzoxazyl, quinazolinyl, quinolinyl, isoquinolinyl, quinoxalinyl, pyridinyl, pyridazinyl, pyrimidinyl, pyrazinyl, pyrrolyl, oxazolyl, indolyl, thiazyl, and the like. Further examples of substituted and unsubstituted heteroaryl rings include:

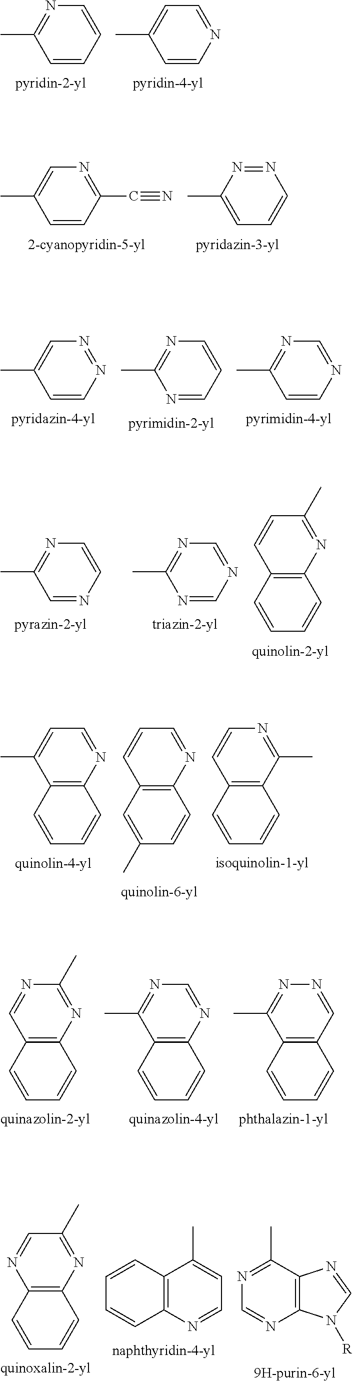

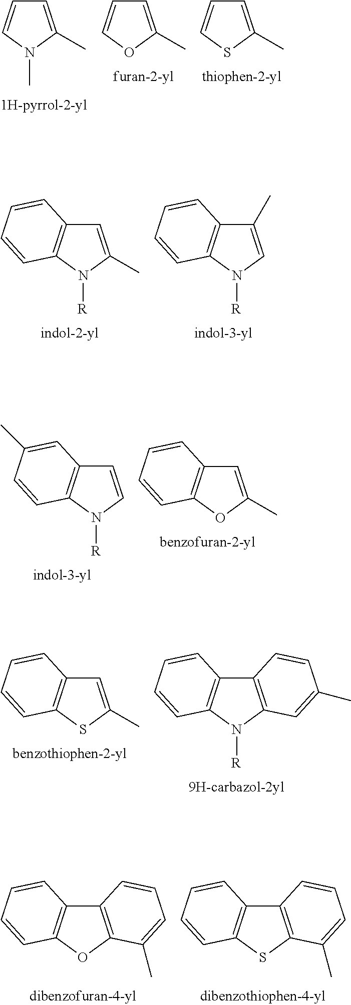

The term “alkoxy” used herein refers to straight or branched chain alkyl radical covalently bonded to the parent molecule through an —O— linkage. Examples of alkoxy groups include, but are not limited to, methoxy, ethoxy, propoxy, isopropoxy, butoxy, n-butoxy, sec-butoxy, t-butoxy and the like.

The term “heteroatom” used herein refers to any atom that is not H (hydrogen) or C (carbon). For example, heteroatom may be S (sulfur), N (nitrogen), or O (oxygen).

The term “cyclic amino” used herein refers to either secondary or tertiary amines in a cyclic moiety. Examples of cyclic amino groups include, but are not limited to, aziridinyl, piperidinyl, N-methylpiperidinyl, and the like.

The term “cyclic imido” used herein refers to an imide in the radical of which the two carbonyl carbons are connected by a carbon chain. Examples of cyclic imide groups include, but are not limited to, 1,8-naphthalimide, pyrrolidine-2,5-dione, 1H-pyrrole-2,5-dione, and the likes.

The term “aryloxy” used herein refers to an aryl radical covalently bonded to the parent molecule through an —O— linkage.

The term “acyloxy” used herein refers to a radical R—C(═O)O—.

The term “carbamoyl” used herein refers to —NHC(═O)R.

The term “keto” and “carbonyl” used herein refers to C═O.

The term “carboxy” used herein refers to —COOH.

The term “ester” used herein refers to C(═O)O.

The term “amido” used herein refers to —NRC(═O)R′.

The term “amino” used herein refers to —NR′R″

As used herein, a substituted group is derived from the unsubstituted parent structure in which there has been an exchange of one or more hydrogen atoms for another atom or group. When substituted, the substituent group(s) is (are) one or more group(s) individually and independently selected from C₁-C₆ alkyl, C₁-C₆ alkenyl, C₁-C₆ alkynyl, C₃-C₇ cycloalkyl (optionally substituted with halo, alkyl, alkoxy, carboxyl, haloalkyl, CN, —SO₂-alkyl, —CF₃, and —OCF₃), cycloalkyl geminally attached, C₁-C₆ heteroalkyl, C₃-C₁₀ heterocycloalkyl (e.g., tetrahydrofuryl) (optionally substituted with halo, alkyl, alkoxy, carboxyl, CN, —SO₂-alkyl, —CF₃, and —OCF₃), aryl (optionally substituted with halo, alkyl, aryl optionally substituted with C₁-C₆ alkyl, arylalkyl, alkoxy, aryloxy, carboxyl, amino, imido, amido (carbamoyl), optionally substituted cyclic imido, cylic amido, CN, —NH—C(═O)-alkyl, —CF₃, and —OCF₃), arylalkyl (optionally substituted with halo, alkyl, alkoxy, aryl, carboxyl, CN, —SO₂-alkyl, —CF₃, and —OCF₃), heteroaryl (optionally substituted with halo, alkyl, alkoxy, aryl, heteroaryl, aralkyl, carboxyl, CN, —SO₂-alkyl, —CF₃, and —OCF₃), halo (e.g., chloro, bromo, iodo and fluoro), cyano, hydroxy, optionally substituted cyclic imido, amino, imido, amido, —CF₃, C₁-C₆ alkoxy, aryloxy, acyloxy, sulfhydryl (mercapto), halo(C₁-C₆)alkyl, C₁-C₆ alkylthio, arylthio, mono- and di-(C₁-C₆)alkyl amino, quaternary ammonium salts, amino(C₁-C₆)alkoxy, hydroxy(C₁-C₆)alkylamino, amino(C₁-C₆)alkylthio, cyanoamino, nitro, carbamoyl, keto (oxy), carbonyl, carboxy, glycolyl, glycyl, hydrazino, guanyl, sulfamyl, sulfonyl, sulfinyl, thiocarbonyl, thiocarboxy, sulfonamide, ester, C-amide, N-amide, N-carbamate, O-carbamate, urea and combinations thereof. Wherever a substituent is described as “optionally substituted” that substituent can be substituted with the above substituents.

### Formulae I-a and I-b

Some embodiments provide a luminescent dye having one of the structures below:

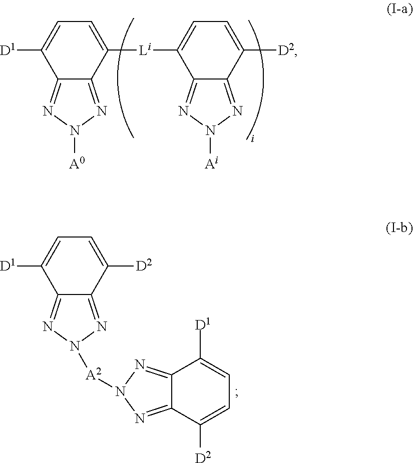

wherein D¹ and D² are electron donating groups, Lⁱ is an electron donor linker, and A⁰ and Aⁱ are electron acceptor groups. In some embodiments, where more than one electron donor group is present, the other electron donor groups may be occupied by another electron donor, a hydrogen atom, or another neutral substituent. In some embodiments, at least one of the D¹, D², and Lⁱ is a group which increases the electron density of the 2H-benzo[d][1,2,3]triazole system to which it is attached.

In formulae I-a and I-b, i is an integer in the range of 0 to 100. In some embodiments, i is an integer in the range of 0 to 50, 0 to 30, 0 to 10, 0 to 5, or 0 to 3. In some embodiments, i is 0, 1, 2, 3, 4, 5, 6, 7, 8, 9, or 10.

In formulae I-a and I-b, A⁰ and Aⁱ are each independently selected from the group consisting of optionally substituted alkyl, optionally substituted alkenyl, optionally substituted heteroalkyl, optionally substituted aryl, optionally substituted heteroaryl, optionally substituted amino, optionally substituted amido, optionally substituted cyclic amido, optionally substituted cyclic imido, optionally substituted alkoxy, and optionally substituted carboxy, and optionally substituted carbonyl.

In some embodiments, A⁰ and Aⁱ are each independently selected from the group consisting of optionally substituted heteroaryl, optionally substituted aryl, optionally substituted cyclic imido, optionally substituted C₁₋₈ alkyl, and optionally substituted C₁₋₈ alkenyl; wherein the substituent for optionally substituted heteroaryl is selected from the group consisting of alkyl, aryl and halogen; the substitutent for optionally substituted aryl is —NR¹—C(═O)R² or optionally substituted cyclic imido, wherein R¹ and R² are as described above.

In some embodiments, A⁰ and Aⁱ are each independently phenyl substituted with a moiety selected from the group consisting of —NR¹—C(═O)R² and optionally substituted cyclic imido, wherein R¹ and R² are as described above.

In some embodiments, A⁰ and Aⁱ are each optionally substituted heteroaryl or optionally substituted cyclic imido; wherein the substituent for optionally substituted heteroaryl and optionally substituted cyclic imido is selected from the group consisting of alkyl, aryl and halogen. In some embodiments, at least one of the A⁰ and Aⁱ is selected from the group consisting of: optionally substituted pyridinyl, optionally substituted pyridazinyl, optionally substituted pyrimidinyl, optionally substituted pyrazinyl, optionally substituted triazinyl, optionally substituted quinolinyl, optionally substituted isoquinolinyl, optionally substituted quinazolinyl, optionally substituted phthalazinyl, optionally substituted quinoxalinyl, optionally substituted naphthyridinyl, and optionally substituted purinyl.

In other embodiments, A⁰ and Aⁱ are each optionally substituted alkyl. In other embodiments, A⁰ and Aⁱ are each optionally substituted alkenyl. In some embodiments, at least one of the A⁰ and Aⁱ is selected from the group consisting of:

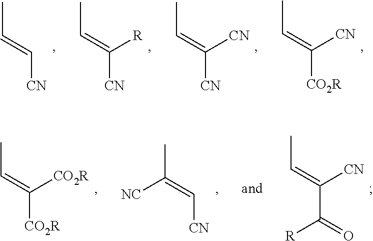

wherein R is optionally substituted alkyl.

In formula I-a and I-b, A² is selected from the group consisting of optionally substituted alkylene, optionally substituted alkenylene, optionally substituted arylene, optionally substituted heteroarylene, ketone, ester, and

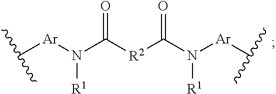

wherein Ar is optionally substituted aryl or optionally substituted heteroaryl. R¹ is selected from the group consisting of H, alkyl, alkenyl, aryl, heteroaryl, aralkyl, alkaryl; and R² is selected from the group consisting of optionally substituted alkylene, optionally substituted alkenylene, optionally substituted arylene, optionally substituted heteroarylene, ketone, and ester; or R¹ and R² may be connected together to form a ring.

In some embodiments, A² is selected from the group consisting of optionally substituted arylene, optionally substituted heteroarylene, and

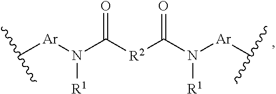

wherein Ar, R¹ and R² are as described above.

In formulae I-a and I-b, D¹ and D² are each independently selected from the group consisting of hydrogen, optionally substituted alkoxy, optionally substituted aryloxy, optionally substituted acyloxy, optionally substituted alkyl, optionally substituted aryl, optionally substituted heteroaryl, optionally substituted amino, amido, cyclic amido, and cyclic imido, provided that D¹ and D² are not both hydrogen.

In some embodiments, D¹ and D² are each independently selected from the group consisting of hydrogen, optionally substituted aryl, optionally substituted heteroaryl, and amino, provided that D¹ and D² are not both hydrogen. In some embodiments, D¹ and D² are each independently selected from the group consisting of hydrogen, optionally substituted aryl, optionally substituted heteroaryl, and diphenylamino, provided that D¹ and D² are not both hydrogen.

In some embodiments, D¹ and D² are each independently optionally substituted aryl. In some embodiments, D¹ and D² are each independently phenyl optionally substituted by alkoxy or amino. In other embodiments, D¹ and D² are each independently selected from hydrogen, optionally substituted benzofuranyl, optionally substituted thiophenyl, optionally substituted furanyl, dihydrothienodioxinyl, optionally substituted benzothiophenyl, and optionally substituted dibenzothiophenyl, provided that D¹ and D² are not both hydrogen.

In some embodiments, the substituent for optionally substituted aryl and optionally substituted heteroaryl may be selected from the group consisting of alkoxy, aryloxy, aryl, heteroaryl, and amino.

In formulae I-a and I-b, Lⁱ is each independently selected from the group consisting of optionally substituted alkylene, optionally substituted alkenylene, optionally substituted alkynylene, optionally substituted arylene, optionally substituted heteroarylene. In some embodiments, Lⁱ is selected from the group consisting of optionally substituted heteroarylene and optionally substituted arylene.

In some embodiments, at least one of the Lⁱ is selected from the group consisting of: 1,2-ethylene, acetylene, 1,4-phenylene, 1,1′-biphenyl-4,4′-diyl, naphthalene-2,6-diyl, naphthalene-1,4-diyl, 9H-fluorene-2,7-diyl, perylene-3,9-diyl, perylene-3,10-diyl, or pyrene-1,6-diyl, 1H-pyrrole-2,5-diyl, furan-2,5-diyl, thiophen-2,5-diyl, thieno[3,2-b]thiophene-2,5-diyl, benzo[c]thiophene-1,3-diyl, dibenzo[b,d]thiophene-2,8-diyl, 9H-carbozole-3,6-diyl, 9H-carbozole-2,7-diyl, dibenzo[b,d]furan-2,8-diyl, 10H-phenothiazine-3,7-diyl, and 10H-phenothiazine-2,8-diyl; wherein each moiety is optionally substituted.

### Formulae II-a and II-b

Some embodiments provide a luminescent dye having one of the structures below:

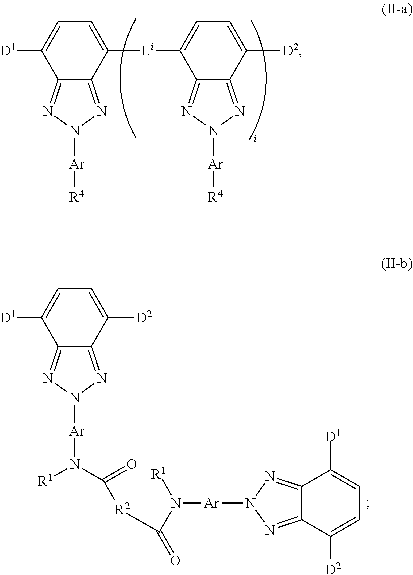

wherein i is an integer in the range of 0 to 100. In some embodiments, i is an integer in the range of 0 to 50, 0 to 30, 0 to 10, 0 to 5, or 0 to 3. In some embodiments, i is 0, 1, 2, 3, 4, 5, 6, 7, 8, 9, or 10.

In formulae II-a and II-b, Ar is optionally substituted aryl or optionally substituted heteroaryl. In some embodiments, aryl substituted with an amido or a cyclic imido group at the N-2 position of the 2H-benzo[d][1,2,3]triazole ring system provides unexpected and improved benefits.

In formulae II-a and II-b, R⁴ is

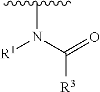

or optionally substituted cyclic imido; R¹ is each independently selected from the group consisting of H, alkyl, alkenyl, aryl, heteroaryl, aralkyl, alkaryl; R³ is each independently selected from the group consisting of optionally substituted alkyl, optionally substituted alkenyl, optionally substituted aryl, optionally substituted heteroaryl; or R′ and R″ may be connected together to form a ring.

In some embodiments, R⁴ is optionally substituted cyclic imido selected from the group consisting of:

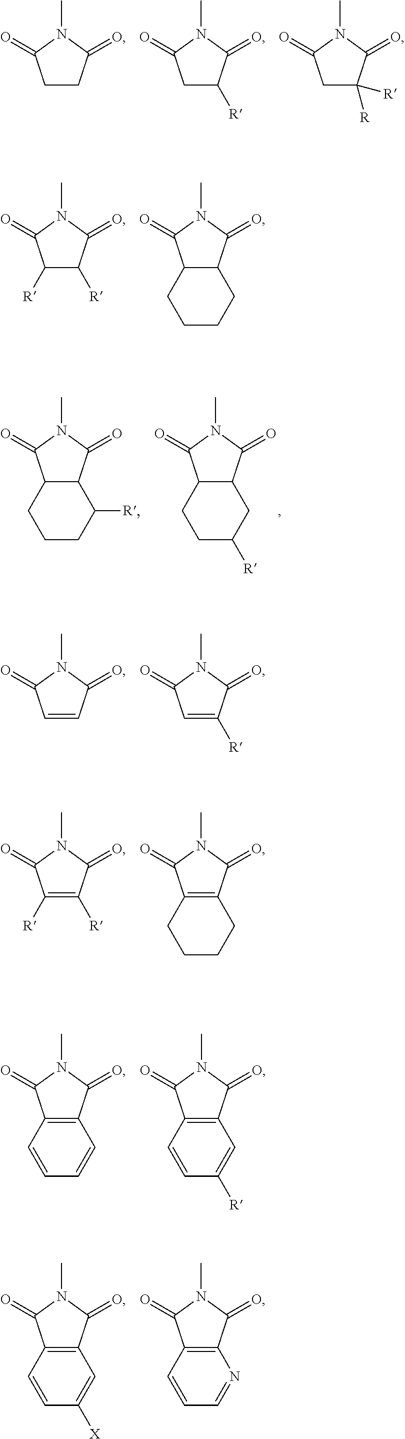

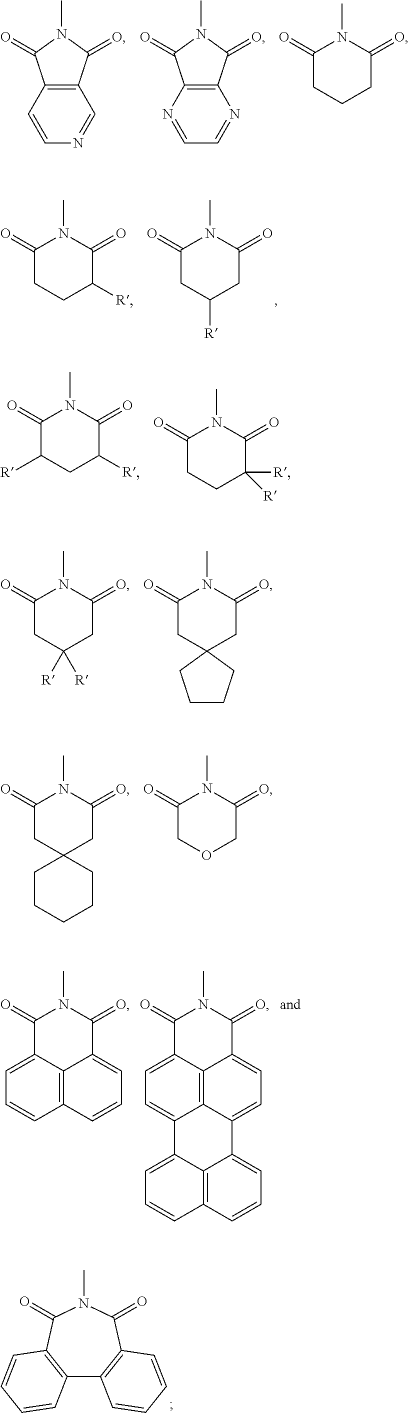

and wherein R′ is each optionally substituted alkyl or optionally substituted aryl; and X is optionally substituted heteroalkyl.

In formulae II-a and II-b, R² is selected from the group consisting of optionally substituted alkylene, optionally substituted alkenylene, optionally substituted arylene, optionally substituted heteroarylene.

In formulae II-a and II-b, D¹ and D² are each independently selected from the group consisting of hydrogen, optionally substituted alkoxy, optionally substituted aryloxy, optionally substituted acyloxy, optionally substituted alkyl, optionally substituted aryl, optionally substituted heteroaryl, optionally substituted amino, amido, cyclic amido, and cyclic imido, provided that D¹ and D² are not both hydrogen.

In formulae II-a and II-b, Lⁱ is independently selected from the group consisting of optionally substituted alkylene, optionally substituted alkenylene, optionally substituted alkynylene, optionally substituted arylene, optionally substituted heteroarylene.

In some embodiments, at least one of the Lⁱ is selected from the group consisting of: 1,2-ethylene, acetylene, 1,4-phenylene, 1,1′-biphenyl-4,4′-diyl, naphthalene-2,6-diyl, naphthalene-1,4-diyl, 9H-fluorene-2,7-diyl, perylene-3,9-diyl, perylene-3,10-diyl, or pyrene-1,6-diyl, 1H-pyrrole-2,5-diyl, furan-2,5-diyl, thiophen-2,5-diyl, thieno[3,2-b]thiophene-2,5-diyl, benzo[c]thiophene-1,3-diyl, dibenzo[b,d]thiophene-2,8-diyl, 9H-carbozole-3,6-diyl, 9H-carbozole-2,7-diyl, dibenzo[b,d]furan-2,8-diyl, 10H-phenothiazine-3,7-diyl, and 10H-phenothiazine-2,8-diyl; wherein each moiety is optionally substituted.

The luminescent dye represented by general formulae (II-a) and (II-b) can be made by known methods, such as those described in International Application No. PCT/US2012/057118, the content of which is hereby incorporated by reference in its entirety.

### Formulae III-a and III-b

Some embodiments provide a luminescent dye having one of the structures below:

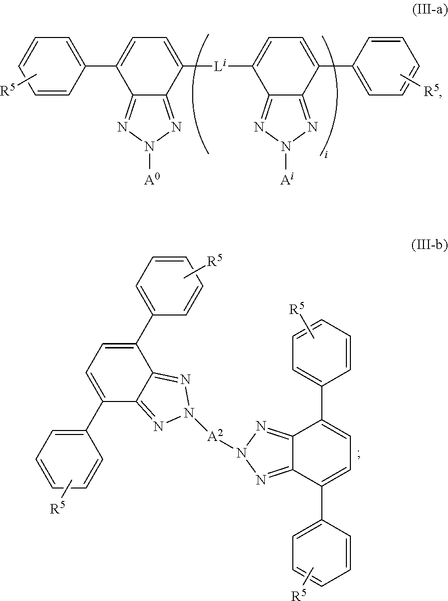

The placement of an alkyl group in formulae (III-a) and (III-b) at the N-2 position of the 2H-benzo[d][1,2,3]triazole ring system along with substituted phenyls at the C-4 and C-7 positions provides unexpected and improved benefits. In formula III-a and III-b, i is an integer in the range of 0 to 100. In some embodiments, i is an integer in the range of 0 to 50, 0 to 30, 0 to 10, 0 to 5, or 0 to 3. In some embodiments, i is 0, 1, 2, 3, 4, 5, 6, 7, 8, 9, or 10.

In formula III-a and III-b, A⁰ and Aⁱ are each independently selected from the group consisting of optionally substituted alkyl, optionally substituted alkenyl, optionally substituted heteroalkyl, optionally substituted amido, optionally substituted alkoxy, optionally substituted cabonyl, and optionally substituted carboxy.

In some embodiments, A⁰ and Aⁱ are each independently unsubstituted alkyl or alkyl substituted by a moiety selected from the group consisting of: —NRR″, —OR, —COOR, —COR, —CONHR, —CONRR″, halo and —CN; wherein R is C₁-C₂₀ alkyl, and R″ is hydrogen or C₁-C₂₀ alkyl. In some embodiments, the optionally substituted alkyl may be optionally substituted C₁-C₄₀ alkyl. In some embodiments, A⁰ and the Aⁱ are each independently C₁-C₄₀ alkyl or C₁-C₂₀ haloalkyl.

In some embodiments, A⁰ and Aⁱ are each independently C₁-C₂₀ haloalkyl, C₁-C₄₀ arylalkyl, or C₁-C₂₀ alkenyl.

In formulae III-a and III-b, each R⁵ is independently selected from the group consisting of optionally substituted alkoxy, optionally substituted aryloxy, optionally substituted acyloxy, and amino. In some embodiments, R⁵ may attach to phenyl ring at ortho and/or para position. In some embodiments, R⁵ is independently selected from C₁-C₄₀ alkoxy,

In formulae III-a and III-b, A² is selected from the group consisting of optionally substituted alkylene, optionally substituted alkenylene, optionally substituted arylene, optionally substituted heteroarylene, ketone, ester, and

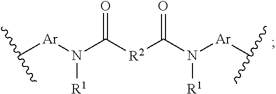

wherein Ar is optionally substituted aryl or optionally substituted heteroaryl, R¹ is selected from the group consisting of H, alkyl, alkenyl, aryl, heteroaryl, aralkyl, alkaryl; and R² is selected from the group consisting of optionally substituted alkylene, optionally substituted alkenylene, optionally substituted arylene, optionally substituted heteroarylene, ketone, and ester; or R¹ and R² may be connected together to form a ring.

In formulae III-a and III-b, Lⁱ is independently selected from the group consisting of optionally substituted alkylene, optionally substituted alkenylene, optionally substituted alkynylene, optionally substituted arylene, optionally substituted heteroarylene.

In some embodiments, at least one of the Lⁱ is selected from the group consisting of: 1,2-ethylene, acetylene, 1,4-phenylene, 1,1′-biphenyl-4,4′-diyl, naphthalene-2,6-diyl, naphthalene-1,4-diyl, 9H-fluorene-2,7-diyl, perylene-3,9-diyl, perylene-3,10-diyl, or pyrene-1,6-diyl, 1H-pyrrole-2,5-diyl, furan-2,5-diyl, thiophen-2,5-diyl, thieno[3,2-b]thiophene-2,5-diyl, benzo[c]thiophene-1,3-diyl, dibenzo[b,d]thiophene-2,8-diyl, 9H-carbozole-3,6-diyl, 9H-carbozole-2,7-diyl, dibenzo[b,d]furan-2,8-diyl, 10H-phenothiazine-3,7-diyl, and 10H-phenothiazine-2,8-diyl; wherein each moiety is optionally substituted.

The luminescent dye represented by general formulae (III-a) and (III-b) can be made by known methods, such as those described in International Application No. PCT/US2012/057118, the content of which is hereby incorporated by reference in its entirety.

### Formula IV

Some embodiments provide a luminescent dye having the structure below:

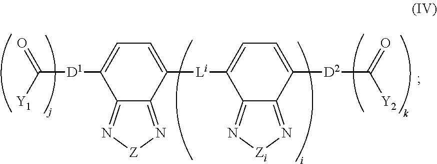

wherein i is an integer in the range of 0 to 100. In some embodiments, i is an integer in the range of 0 to 50, 0 to 30, 0 to 10, 0 to 5, or 0 to 3. In some embodiments, i is 0, 1, 2, 3, 4, 5, 6, 7, 8, 9, or 10.

In formula IV, Z and Z, are each independently selected from the group consisting of —O—, —S—, —Se—, —Te—, —NR⁶—, —CR⁶═CR⁶—, and —CR⁶═N—, wherein R⁶ is hydrogen, optionally substitute C₁-C₆ alkyl, or optionally substituted C₁-C₁₀ aryl; and

In formula IV, D¹ and D² are independently selected from the group consisting of optionally substituted alkoxy, optionally substituted aryloxy, optionally substituted acyloxy, optionally substituted alkyl, optionally substituted aryl, optionally substituted heteroaryl, optionally substituted amino, amido, cyclic amido, and cyclic imido; j is 0, 1 or 2, and k is 0, 1, or 2. In some embodiments, the —C(═O)Y₁ and —C(═O)Y₂ groups may attach to the substituent(s) of the optionally substituted moiety for D¹ and D².

In formula IV, Y₁ and Y₂ are independently selected from the group consisting of optionally substituted aryl, optionally substituted alkyl, optionally substituted cycloalkyl, optionally substituted alkoxy, and optionally substituted amino; and

In formula IV, Lⁱ is independently selected from the group consisting of optionally substituted alkylene, optionally substituted alkenylene, optionally substituted alkynylene, optionally substituted arylene, optionally substituted heteroarylene.

In some embodiments, at least one of the Lⁱ is selected from the group consisting of: 1,2-ethylene, acetylene, 1,4-phenylene, 1,1′-biphenyl-4,4′-diyl, naphthalene-2,6-diyl, naphthalene-1,4-diyl, 9H-fluorene-2,7-diyl, perylene-3,9-diyl, perylene-3,10-diyl, or pyrene-1,6-diyl, 1H-pyrrole-2,5-diyl, furan-2,5-diyl, thiophen-2,5-diyl, thieno[3,2-b]thiophene-2,5-diyl, benzo[c]thiophene-1,3-diyl, dibenzo[b,d]thiophene-2,8-diyl, 9H-carbozole-3,6-diyl, 9H-carbozole-2,7-diyl, dibenzo[b,d]furan-2,8-diyl, 10H-phenothiazine-3,7-diyl, and 10H-phenothiazine-2,8-diyl; wherein each moiety is optionally substituted.

With regard to Lⁱ in any of the formulae above, the electron linker represents a conjugated electron system, which may be neutral or serve as an electron donor itself. In some embodiments, some examples are provided below, which may or may not contain additional attached substituents.

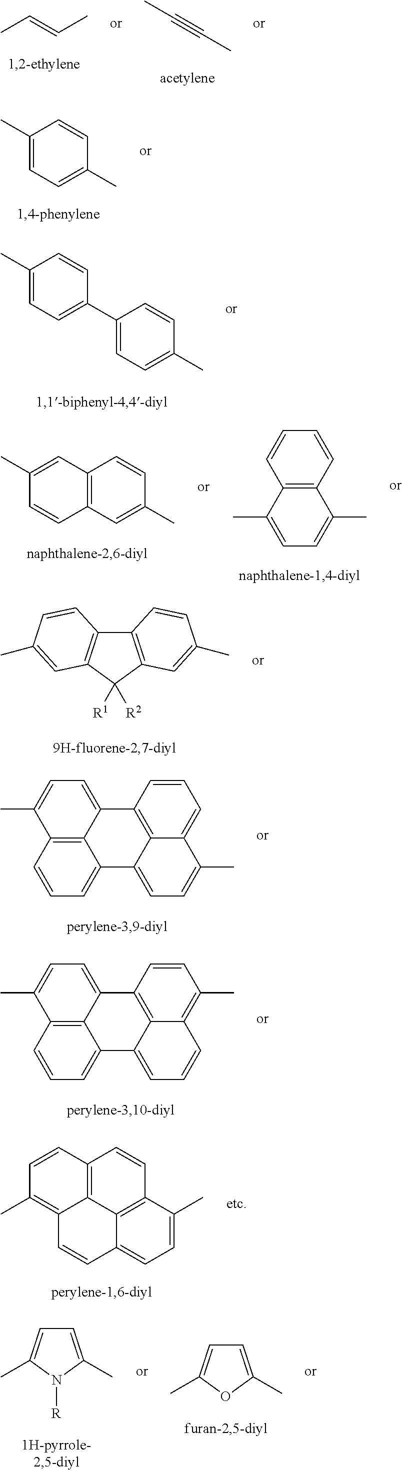

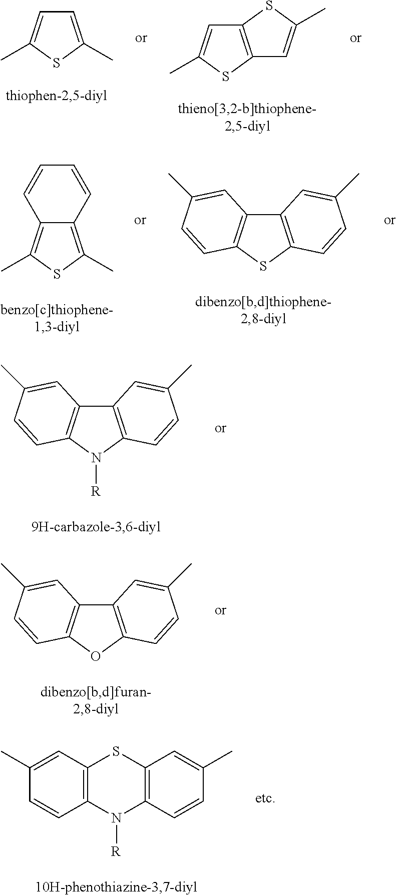

The luminescent dye represented by general formulae (IV) can be made by known methods, such as those described in International Application No. PCT/US2012/057118, the content of which is hereby incorporated by reference in its entirety.

### Formulae V-a and V-b

Some embodiments provide a perylene diester derivative represented by the following general formula (V-a) or general formula (V-b):

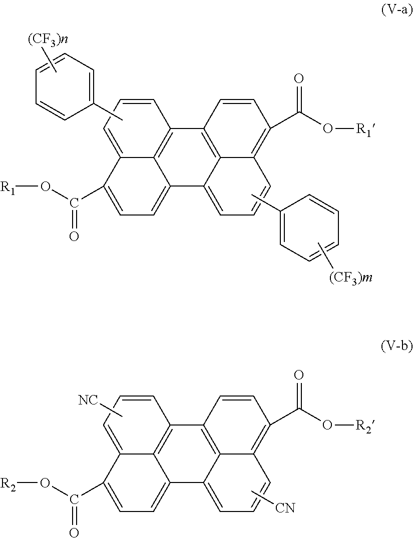

wherein R₁ and R₁′ in formula (V-a) are each independently selected from the group consisting of hydrogen, C₁-C₁₀ alkyl, C₃-C₁₀ cycloalkyl, C₂-C₁₀ alkoxyalkyl, C₆-C₁₈ aryl, and C₆-C₂₀ aralkyl; m and n in formula (V-a) are each independently in the range of from 1 to 5; and R₂ and R₂′ in formula (V-b) are each independently selected from the group consisting of a C₆-C₁₈ aryl and C₆-C₂₀ aralkyl. In some embodiments, if one of the cyano groups on formula (V-b) is present on the 4-position of the perylene ring, then the other cyano group is not present on the 10-position of the perylene ring. In some embodiments, if one of the cyano groups on formula (V-b) is present on the 10-position of the perylene ring, then the other cyano group is not present on the 4-position of the perylene ring.

In some embodiments, R₁ and R₁′ are independently selected from the group consisting of hydrogen, C₁-C₆ alkyl, C₂-C₆ alkoxyalkyl, and C₆-C₁₈ aryl. In some embodiments, R₁ and R₁′ are each independently selected from the group consisting of isopropyl, isobutyl, isohexyl, isooctyl, 2-ethyl-hexyl, diphenylmethyl, trityl, and diphenyl. In some embodiments, R₂ and R₂′ are independently selected from the group consisting of diphenylmethyl, trityl, and diphenyl. In some embodiments, each m and n in formula (V-a) is independently in the range of from 1 to 4.

The perylene diester derivative represented by the general formula (V-a) or general formula (V-b) can be made by known methods, such as those described in WO 2012/094409, the content of which is hereby incorporated by reference in its entirety.

In some embodiments, two or more luminescent dyes are mixed together in a single luminescent medium layer. In some embodiments, two or more luminescent medium layers can be present, each of which can comprise the same or different luminescent dyes.

The amount of luminescent dye used in any luminescent medium layer can vary. In some embodiments, the luminescent dye is present in the polymer matrix of the luminescent medium layer in an amount in the range of about 0.01 wt % to about 3.0 wt %. In some embodiments, the luminescent dye is present in the polymer matrix of the luminescent medium layer in an amount in the range of about 0.05 wt % to about 1.0 wt %.

The overall thickness of the microstructured wavelength conversion thin film may also vary over a wide range. In some embodiments, the microstructured wavelength conversion film thickness is in the range of about 0.1 μm to about 1 mm. In some embodiments, the microstructured wavelength conversion film thickness is in the range of about 0.5 μm to about 0.5 mm. The thicknesses of each individual layer of the microstructured wavelength conversion film can be independently selected. In some embodiments, the microstructured polymer layer thickness is in the range of about 0.1 μm to about 1 mm, preferably about 0.5 μm to about 0.5 mm. In some embodiments, the luminescent medium layer thickness is in the range of about 0.1 μm to about 1 mm, preferably about 0.5 μm to about 0.5 mm

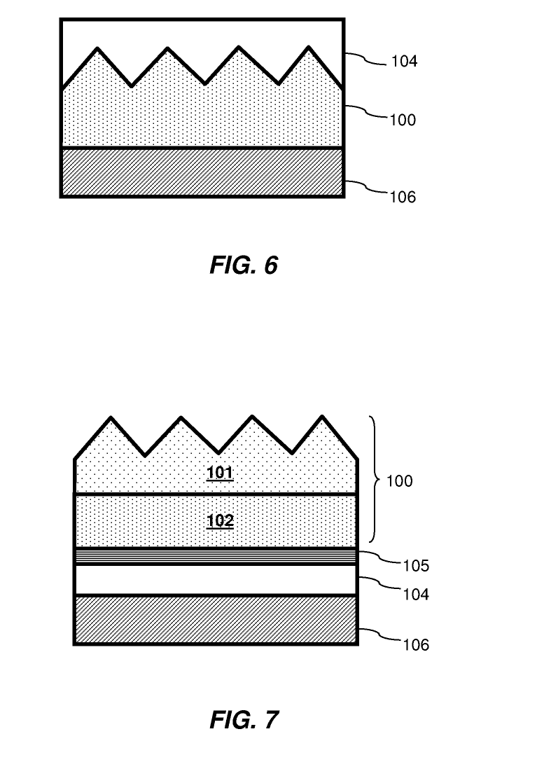

Some embodiments provide a method for improving the performance of a solar energy conversion device comprising applying a microstructured wavelength conversion film directly onto the light incident side of the solar energy conversion device, as illustrated, for example, in FIGS. 5, 7, and 8. Some embodiments provide a method for improving the performance of a solar energy conversion device, comprising incorporating a microstructured wavelength conversion film into the solar energy conversion device during fabrication, so that the microstructured wavelength conversion film is encapsulated between the photovoltaic device or solar cell and its cover substrate (i.e., light incident surface) on the light incident side, as illustrated, for example, in FIGS. 6, 9, and 10.

In some embodiments the cover substrate (or light incident surface) is a glass plate. In other embodiments, the cover substrate comprises a polymer material selected from the group consisting of polyethylene terephthalate, polymethyl methacrylate, polyvinyl butyral, ethylene vinyl acetate, ethylene tetrafluoroethylene, polyimide, polycarbonate, polystyrene, siloxane sol-gel, polyurethane, polyacrylate, and combinations thereof.

In some embodiments, the microstructured wavelength conversion film 100 is directly attached to the light incident surface 104 for the solar cell, as shown in FIG. 5. A refractive index matching liquid 105 is applied between the microstructured wavelength conversion film and the light incident surface of the solar cell 106 to ensure better light out-coupling efficiency. In some embodiments the light incident surface 104 of the solar cell 106 is a glass plate. In some embodiments the light incident surface 104 of the solar cell 106 comprises a polymer material selected from the group consisting of polyethylene terephthalate, polymethyl methacrylate, polyvinyl butyral, ethylene vinyl acetate, ethylene tetrafluoroethylene, polyimide, polycarbonate, polystyrene, siloxane sol-gel, polyurethane, polyacrylate, and combinations thereof.

In some embodiments, the microstructured wavelength conversion film 100 is fabricated directly into the module as the encapsulation layer between the optically transparent light incident surface 104 of the module and the photovoltaic device or solar cell 106, as shown in FIG. 6. In some embodiments, the microstructured polymer layer 101 and the luminescent medium layer 102 are directly attached to the light incident surface 104 of the device, as shown in FIG. 7. A refractive index matching liquid 105 may be applied between the luminescent medium layer and the light incident surface of the solar cell 106 to ensure better light out-coupling efficiency.

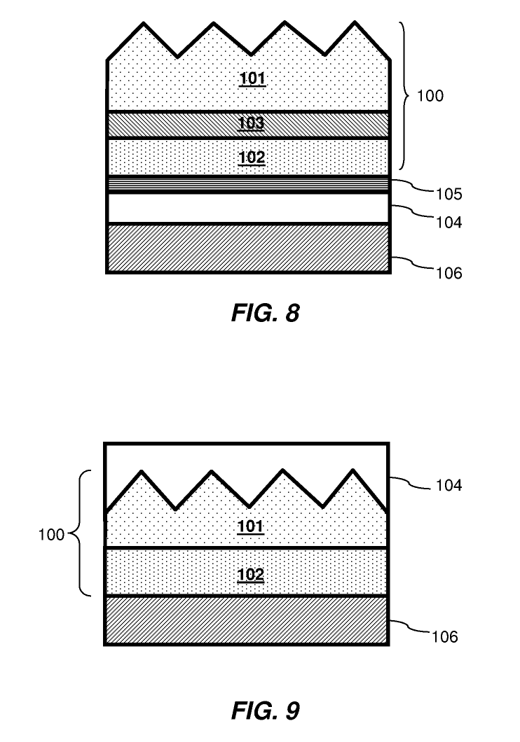

In some embodiments, the microstructured polymer layer 101 and a luminescent medium layer 102 are directly attached to the light incident surface 104 of the device, as shown in FIG. 8. A refractive index matching liquid 105 may be applied between the luminescent medium layer and the light incident surface 104 of the solar cell 106 to ensure better light out-coupling efficiency. Other medium layer(s) 103 may be interposed between the microstructured polymer layer and the luminescent medium layer. In some embodiments the other medium layer 103 is a glass plate. In some embodiments the other medium layer 103 comprises a polymer material selected from the group consisting of polyethylene terephthalate, polymethyl methacrylate, polyvinyl butyral, ethylene vinyl acetate, ethylene tetrafluoroethylene, polyimide, polycarbonate, polystyrene, siloxane sol-gel, polyurethane, polyacrylate, and combinations thereof. In some embodiments the other medium layer 103 comprises a luminescent dye.

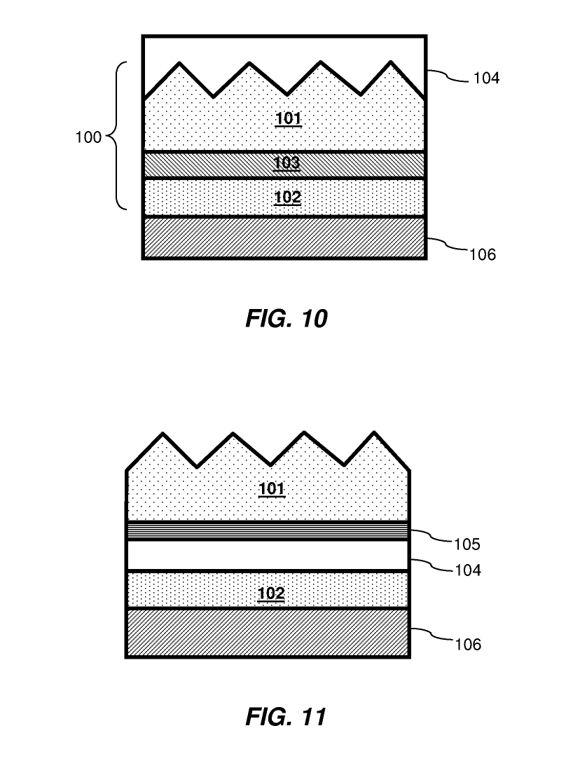

In some embodiments, the microstructured polymer layer 101 and a luminescent medium layer 102 are fabricated directly into the module as the encapsulation layer between the optically transparent light incident surface 104 of the module and the solar cell 106, as shown in FIG. 9. In some embodiments, the microstructured polymer layer 101 and a luminescent medium 102 are fabricated directly into the module as the encapsulation layer between the optically transparent light incident surface 104 of the module and the photovoltaic device or solar cell 106, as shown in FIG. 10. Other medium layer(s) 103 may be interposed between the microstructured polymer layer and the luminescent medium layer.

Some embodiments provide a method for improving the performance of a solar energy conversion device, comprising incorporating a microstructured wavelength conversion film to the solar energy device, wherein the microstructured polymer layer 101 is applied onto the light incident side of the solar energy conversion device, or the light incident surface for the solar cell, and the luminescent medium layer is incorporated into the solar energy conversion device during its fabrication. As illustrated in FIG. 11, the microstructured polymer layer 101 is applied onto the light incident surface 104 for the solar cell 106, and the luminescent medium layer 102 is positioned between the light incident surface 104 and the solar cell 106. In some embodiments, a refractive index matching liquid is used to attach the microstructured polymer layer 101 to the light incident surface 104.

In some embodiments, the microstructured polymer layer 101 is directly attached to the light incident surface of the device 104, as shown in FIG. 11. A refractive index matching liquid 105 is applied between the microstructured polymer layer and the light incident surface of the solar cell 104 to ensure better light out-coupling efficiency. The luminescent medium layer 102 is fabricated directly into the solar cell as the encapsulation layer between the optically transparent light incident surface of the module 104 and the solar cell 106.

Various types of photovoltaic devices or solar cells can be improved using the microstructured wavelength conversion films disclosed herein. In some embodiments, the photovoltaic device or solar cell comprises a Cadmium Sulfide/Cadmium Telluride (CdS/CdTe) solar cell. In some embodiments, the photovoltaic device or solar cell comprises a Copper Indium Gallium Diselenide (CIGS) solar cell. In some embodiments, the photovoltaic device or solar cell comprises an amorphous Silicon (a-Si) solar cell. In some embodiments, the photovoltaic device or solar cell comprises a microcrystalline Silicon (μc-Si) solar cell. In some embodiments, the photovoltaic device or solar cell comprises a crystalline Silicon (c-Si) solar cell.

In some embodiments of the inventions, a refractive index matching liquid or optical adhesive is used to attach the microstructured polymer layer to the light incident surface of the photovoltaic device or solar cell. In some embodiments the refractive index matching liquid used is a Series A mineral oil comprising aliphatic and alicyclic hydrocarbons, and hydrogenated terphenyl from Cargille-Sacher Labratories, Inc.

In some embodiments, the solar cell efficiency enhancement is measured first with a plain wavelength conversion film (no microstructures) and then with a microstructured wavelength conversion film under one sun irradiation (AM1.5G) by using a Newport solar simulator system. The efficiency enhancement of the CdS/CdTe solar cell with both the plain and microstructured wavelength conversion film is determined by the equation below:

Efficiency Enhancement=(η_{cell+film}−η_{cell})η_{cell}*100%

In some embodiments, a CdS/CdTe solar cell is modified with a plain wavelength conversion film according to the method disclosed herein, and the efficiency enhancement is determined to be 13.8%, then a microstructured polymer layer is added, and the efficiency enhancement is determined to be greater than 16.8%. In some embodiments, a CdS/CdTe solar cell is modified with a plain wavelength conversion film and the efficiency enhancement is determined to be 14.2%, then a microstructured polymer layer is added, and the efficiency enhancement is determined to be 17.1%. In other embodiments, a CdS/CdTe solar cell is modified with a microstructured wavelength conversion film and the efficiency enhancement is determined to be greater than 12%. In some embodiments, a CdS/CdTe solar cell is modified with a microstructured wavelength conversion film and the efficiency enhancement is determined to be greater than 14%. In some embodiments, a CdS/CdTe solar cell is modified with a microstructured wavelength conversion film and the efficiency enhancement is determined to be greater than 16%.

In other embodiments, a CIGS solar cell is modified with a plain wavelength conversion film according to the method disclosed herein, and the efficiency enhancement is determined to be 10%, then a microstructured polymer layer is added, and the efficiency enhancement is determined to be 11.3%. In some embodiments, a CIGS solar cell is modified with a microstructured wavelength conversion film and the efficiency enhancement is determined to be greater than 10%. In some embodiments, a CIGS solar cell is modified with a microstructured wavelength conversion film and the efficiency enhancement is determined to be greater than 12%. In some embodiments, a CIGS solar cell is modified with a microstructured wavelength conversion film and the efficiency enhancement is determined to be greater than 13%.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the examples which follow.

### EXAMPLES

### Synthesis of Luminescent Dyes

### Intermediate A

Common Intermediate A is synthesized using a two-step procedure.

### Step 1: Synthesis of 2-(Pyridin-4-yl)-2H-benzo[d][1,2,3]-triazole

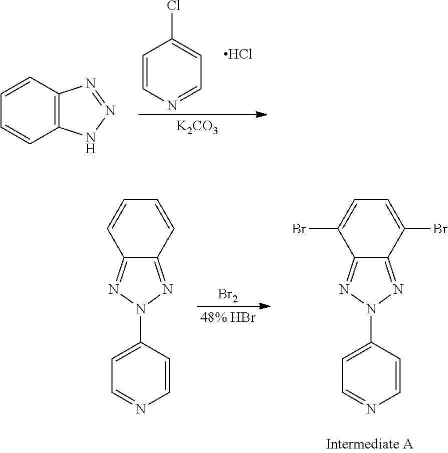

A mixture of 4-chloropyridinium hydrochloride (25.0 g, 166 mmol), benzotriazole (29.6 g, 249 mmol), potassium carbonate (69.1 g, 500 mmol), and dimethylformamide (500 mL) was stirred and heated under argon at 130° C. for 3 days. After cooling, the solid was filtered off, and the solvent was evaporated under reduced pressure. The residue was treated with dichloromethane (200 mL), filtered and chromatographed using a column filled with silica gel (500 mL) and hexane/ethyl acetate (1:1) as an eluent. Fractions containing the desired product were combined, and the solvent was distilled off. The residue was triturated with ethanol, the solid was filtered off and dried in a vacuum oven to give 2-(pyridin-4-yl)-2H-benzo[d][1,2,3]triazole, 6.45 g (20%). 1H NMR (400 MHz, CDCl₃): δ 8.80 (m, 2H, pyridine), 8.26 (m, 2H, pyridine), 7.93 (m, 2H, benzotriazole), 7.46 (m, 2H, benzotriazole).

### Step 2: Synthesis of Intermediate A—4,7-Dibromo-2-(pyridin-4-yl)-2H-benzo[d][1,2,3]triazole)

A mixture of 2-(pyridin-4-yl)-2H-benzo[d][1,2,3]triazole (6.42 g, 32.7 mmol), bromine (5.20 mL, 100 mmol) and 48% HBr (50 mL) was heated at 120° C. for 40 h. The reaction mixture was poured into ice/water (500 mL), treated with 5N NaOH to pH 8, and the excess of bromine was removed by addition of 1M sodium thiosulfate (test with KI/starch paper). After stirring for 30 minutes, the solid was filtered off, washed with water and dried in a vacuum oven. The crude product was purified by column chromatography (silica gel, dichloromethane/ethyl acetate 9:1) and washing with ethyl acetate (50 mL) to give 4,7-dibromo-2-(pyridin-4-yl)-2H-benzo[d][1,2,3]triazole (Intermediate A) 5.00 g (43%). ¹H NMR (400 MHz, CDCl₃): δ 8.85 (m, 2H, pyridine), 8.33 (m, 2H, pyridine), 7.53 (s, 2H, benzotriazole).

### Intermediates B and C

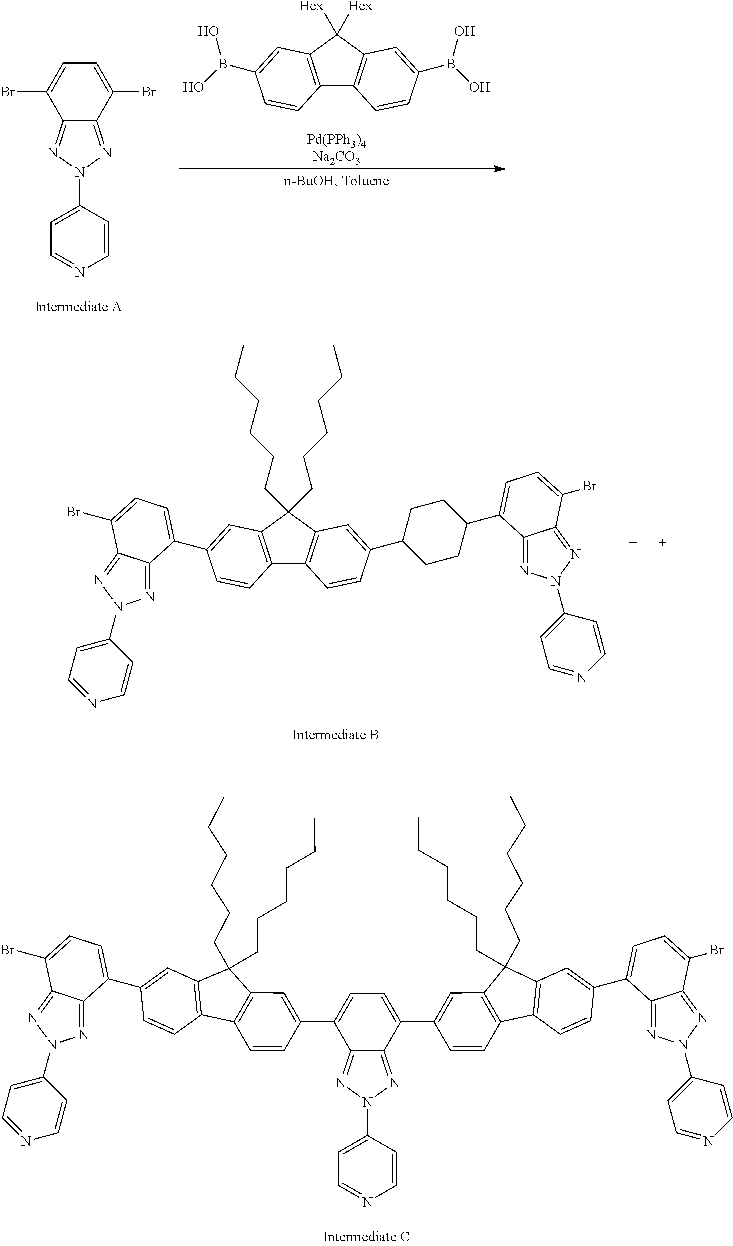

A mixture of Intermediate A (90%, 13.77 g, 35 mmol), 9,9-dihexylfluorene-2,7-diboronic acid (5.06 g, 12 mmol), sodium carbonate (4.24 g, 40 mmol) in water (25 mL), tetrakis(triphenylphosphine)palladium (0) (2.00 g, 1.72 mmol), n-butanol (60 mL), and toluene (80 mL) was stirred and heated under argon at 110° C. for 48 hours. The reaction mixture was poured into water (300 mL), treated with 5N NaOH (30 mL), stirred for 1 hour, and extracted with dichloromethane (4×400 mL). The volatiles were removed under reduced pressure, and the residue was chromatographed (silica gel, dichloromethane/tetrahydrofuran 9:1). The first fraction gave recovered starting material Intermediate A (5.00 g, 36%).

The material from the second fraction was washed with acetone (20 mL) and dried in a vacuum oven to give 2,7-bis(7-bromo-2-(pyridin-4-yl)-2H-benzo[d][1,2,3]triazol-4-yl)-9,9-dihexylfluorene (Intermediate B), yellow crystals, 4.52 g (purity 90%, yield 39%). The third fraction gave Intermediate C, yellow crystals, 1.65 g (purity 80%, yield 39%).

### Compounds 1 and 2

A perylene diester derivative, which is a preferred but non limiting embodiment of the invention as disclosed herein, can be synthesized using a two-step process.

### Step 1: Synthesis of Diisobutyl 4,10-dibromoperylene-3,9-dicarboxylate

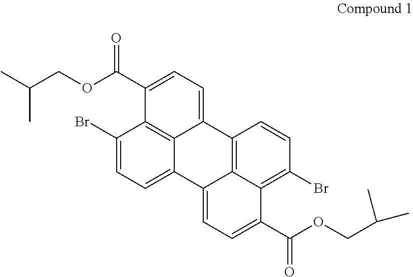 [SMILES: CC(C)COC(=O)c1ccc2c3ccc(Br)c4c(C(=O)OCC(C)C)ccc(c5ccc(Br)c1c52)c43]

To synthesize diisobutyl 4,10-dibromoperylene-3,9-dicarboxylate (“Compound 1”), N-bromosuccinimide (7.85 g, 44 mol) was added to a solution of perylenedicarboxylic acid diisobutyl ester, which can be purchased from Aldrich Chemical Co. Perylenedicarboxylic diisobutyl ester was also synthesized from the corresponding di-acid derivative by esterification with isobutyl alcohol in DMF (50 ml) under heat at 65° C. for 3 hours (until the initial suspension changes to a clear solution). After cooling, methanol (500 ml) was added to the stirred reaction mixture. Soon heavy precipitate was formed, which was separated by filtration, washed with a small portion of cold methanol, and dried in a vacuum oven to give the above Compound 1 as a yellow solid, pure by ¹H NMR (9.6 g, 78%).

### Step 2: Synthesis of Diisobutyl 4,10-bis(4-(trifluoromethyl)phenyl)perylene-3,9-dicarboxylate

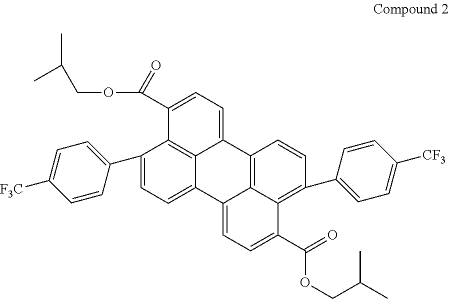 [SMILES: CC(C)COC(=O)c1ccc2c3ccc(-c4ccc(C(F)(F)F)cc4)c4c(C(=O)OCC(C)C)ccc(c5ccc(-c6ccc(C(F)(F)F)cc6)c1c25)c43]

To synthesize diisobutyl 4,10-bis(4-(trifluoromethyl)phenyl)perylene-3,9-dicarboxylate (“Compound 2”), tetrakis(triphenylphosphine)palladium(0) (500 mg, 0.43 mmol) was added to a solution of Compound 1 (3.05 g, 5 mmol), 4-trifluoromethylphenylboronic acid (2.09 g, 11.0 mmol) in a mixture of toluene (50 mL), an aqueous solution of 2M Na₂CO₃ (20 mL), and ethanol (30 mL) under argon atmosphere. The reaction mixture was heated at 90° C. for 1 hour (until clear separation of the organic, water, and solid was observed). The organic layer was separated, filtered through Celite to remove the palladium catalyst, then the solvent was partially removed under vacuum. The product was precipitated from methanol, filtrated off, washed with cold methanol, and dried in a vacuum oven to give pure Compound 2 (by ¹H NMR) as a yellow solid (3.30 g, 89%). Alternative purification was performed by column chromatography (silica gel and a mixture of hexane-ethyl acetate 4:1 as mobile phase).

### Compounds 3, 4, and 5

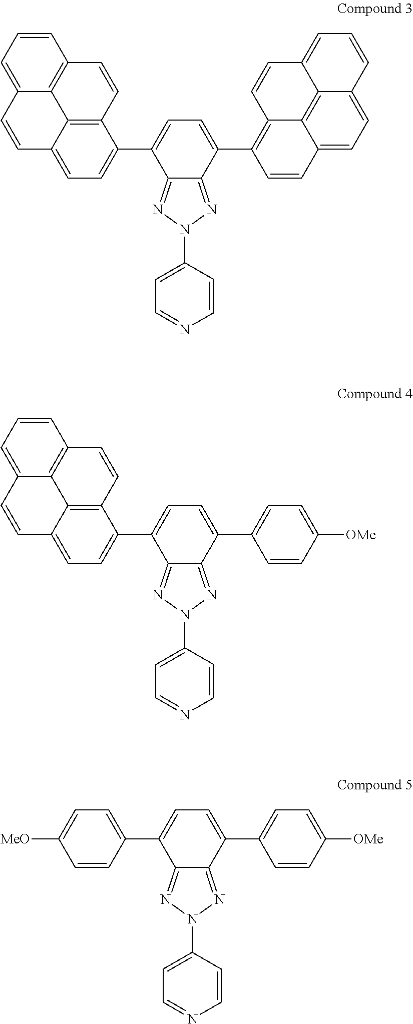 [SMILES: c1cc2ccc3ccc(-c4ccc(-c5ccc6ccc7cccc8ccc5c6c78)c5nn(-c6ccncc6)nc45)c4ccc(c1)c2c34 ; COc1ccc(-c2ccc(-c3ccc4ccc5cccc6ccc3c4c56)c3nn(-c4ccncc4)nc23)cc1 ; COc1ccc(-c2ccc(-c3ccc(OC)cc3)c3nn(-c4ccncc4)nc23)cc1]

A mixture of Intermediate A (1.41 g, 4 mmol), pyrene-1-boronic acid (1.23 g, 5.0 mmol), 4-methoxyphenylboronic acid (0.76 g, 5.0 mmol), sodium carbonate (2.12 g, 20 mmol) in water (10 mL), tetrakis(triphenylphosphine)palladium (0) (0.50 g, 0.43 mmol), n-butanol (30 mL), and toluene (20 mL) was heated under argon at 110° C. for 4 hours. Thin layer chromatography (TLC) of the reaction mixture indicated no starting material left. The reaction mixture was poured into water (200 mL) and extracted with dichloromethane (3×200 mL). The extract was dried over anhydrous sodium carbonate, and the volatiles were removed under reduced pressure. The residue was chromatographed (silica gel, dichloromethane/ethyl acetate 95:5). The first fraction gave 4,7-di(pyren-1-yl)-2-(pyridin-4-yl)-2H-benzo[d][1,2,3]triazole (Compound 3) (610 mg, 25%) as orange crystals. The second fraction gave 4-(4-methoxyphenyl)-7-(pyren-1-yl)-2-(pyridin-4-yl)-2H-benzo[d][1,2,3]triazole (Compound 4) (980 mg, 49%) as orange-yellow crystals. The third fraction gave 4,7-bis(4-methoxyphenyl)-2-(pyridin-4-yl)-2H-benzo[d][1,2,3]triazole (Compound 5) (160 mg, 10%) as yellow crystals.

### Compounds 6, 7, and 8

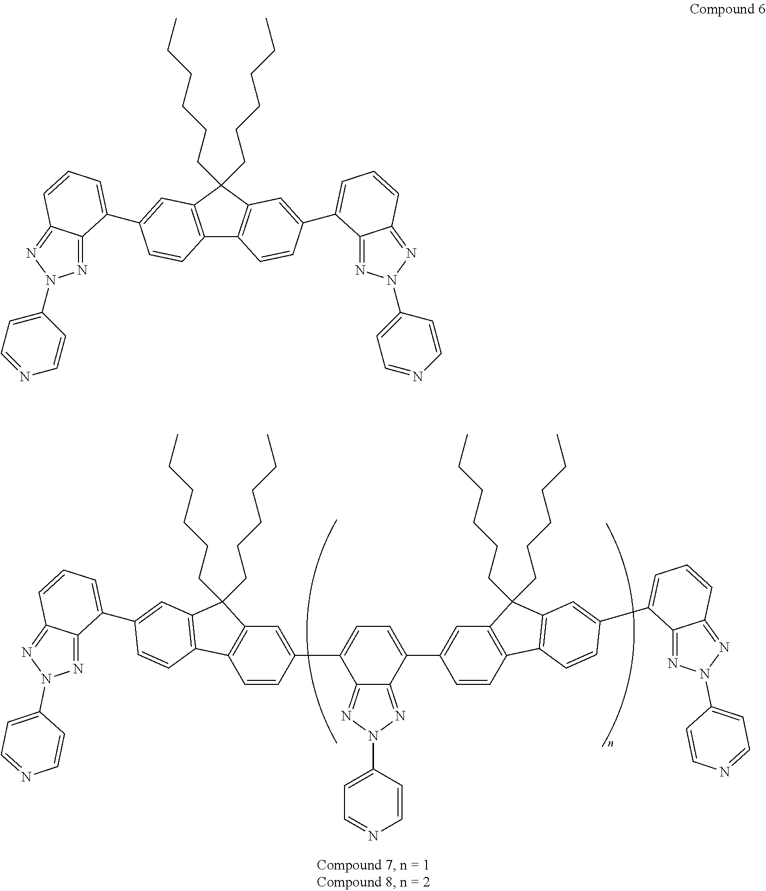

A mixture of Intermediate A (3.52 g, 10 mmol), 9,9-dihexylfluorene-2,7-diboronic acid (1.90 g, 4.5 mmol), sodium carbonate (2.12 g, 20 mmol) in water (10 mL), tetrakis(triphenylphosphine)palladium (0) (1.00 g, 0.86 mmol), n-butanol (80 mL), and toluene (20 mL) was stirred and heated under argon at 110° C. After 48 hours, 1-bromo-4-butylbenzene (3.0 mL, 17 mmol) was added followed by sodium carbonate (2.12 g, 20 mmol) in water (10 mL) and tetrakis(triphenylphosphine)palladium (0) (1.00 g, 0.86 mmol), and heating was continued for an additional 20 hours. The reaction mixture was poured into water (200 mL and extracted with ethyl acetate). The extract was dried over anhydrous sodium sulfate, the volatiles were removed under reduced pressure, and the residue was chromatographed (silica gel, dichloromethane/ethyl acetate 3:1). The first fraction gave Intermediate B (414 mg, 10%). The material from the second fraction was recrystallized from ethanol to give 2,7-bis(2-(pyridin-4-yl)-2H-benzo[d][1,2,3]triazol-4-yl)-9,9-dihexylfluorene (Compound 6) as yellow-green crystals (335 mg, 10%). The third fraction gave dye Compound 7 as yellow crystals (480 mg, 12%). The forth fraction gave dye Compound 8, yellow crystals (75 mg, 2%).

### Compound 9

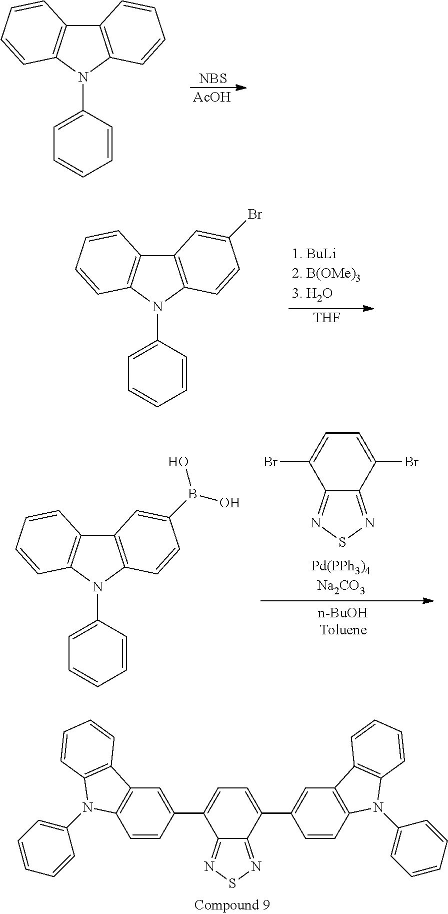

A mixture of 9-phenyl-9H-carbazole 5.44 g (22.4 mmol), N-Bromosuccinimide (NBS) (4.27 g, 24 mmol) and acetic acid (125 mL) was stirred at room temperature for 16 hours and then at 40° C. for 4 hours. The reaction mixture was poured onto crushed ice (500 g), set aside for 6 hours, and finally it was extracted with benzene/ethyl acetate (100 mL/100 mL). The extract was washed with water (200 mL), followed by 1 M sodium carbonate (100 mL) and again water (200 mL). The solution was dried over magnesium sulfate, filtered, and the solvent was removed under reduced pressure to give crude 3-bromo-9-phenyl-9H-carbazole (6.94 g), which was directly used for the next step without any further purification.

To a solution of crude 3-bromo-9-phenyl-9H-carbazole (6.94 g) in anhydrous tetrahydrofuran (THF) stirred under argon and cooled in a dry ice/acetone bath was added 2.2 M n-BuLi in hexane (11.3 mL, 25 mmol), and the obtained mixture was stirred at −76° C. for 1 hour. Trimethyl borate (3.3 mL, 30 mL) was then added, and the reaction mixture was allowed to warm up slowly to room temperature overnight. The mixture was treated with 1 M HCl, stirred for 1 hour, poured into water (200 mL), and extracted with ethyl acetate (2×200 mL). The extract was washed with saturated sodium bicarbonate, dried over magnesium sulfate, and the solvent was removed under reduced pressure. The residue was chromatographed (silica gel, dichloromethane/ethyl acetate, 3:1) to provide (9-phenyl-9H-carbazol-3-yl)boronic acid (1.98 g).

A mixture of 4,7-dibromobenzo[c][1,2,5]thiadiazole (440 mg, 1.5 mmol), (9-phenyl-9H-carbazol-3-yl)boronic acid (1.00 g, 3.48 mmol), sodium carbonate (1.06 g, 10 mmol) in water (6 mL), tetrakis(triphenylphosphine)palladium (346 mg, 0.3 mmol), n-butanol (20 ml), and toluene (20 mL) was stirred under argon and heated at 100° C. for 3 days. The reaction mixture was poured into water (100 mL), acidified to pH 2 with 1 M HCl, stirred for 1 hour, and extracted with dichloromethane (2×200 mL). The dichloromethane was evaporated under atmospheric pressure, and the remaining solvents were removed under reduced pressure at 90° C. Column chromatography of the residue (silica gel, hexane/dichloromethane, 2:1) and triturating of the obtained material with ethanol yielded pure Compound 9 (835 mg), as orange crystals.

### Example 1

A microstructured wavelength conversion film, which comprises a luminescent medium layer 100 comprising an optically transparent polymer matrix and at least one luminescent dye was manufactured with a top surface textured with predefined structures, as illustrated in FIG. 2.

First, the luminescent medium layer is fabricated by (i) preparing a Polyvinyl butyral (PVB) polymer solution by dissolving a PVB powder (from Aldrich and used as received) in TCE (from Aldrich and used as received) at a predetermined ratio of 20 wt %; (ii) preparing a luminescent dye containing a PVB matrix by mixing the PVB polymer solution with the synthesized Compound 2 at a weight ratio (Compound 2/PVB) of 0.3 wt % to obtain a dye-containing polymer solution; (iii) forming the dye/polymer thin film by directly casting the dye-containing polymer solution onto a glass substrate, then heat treating the substrate from room temperature up to 100° C. in 2 hours, completely removing the remaining solvent by further vacuum heating at 130° C. overnight; and (iv) peeling off the dye/polymer thin film under the water and then drying out the free-standing polymer film before forming the microstructures; (v) the film thickness was 250 μm, which can be adjusted by varying the dye/polymer solution concentration and evaporation speed.

Then, the microstructures are formed on the top surface of the luminescent medium layer by embossing at elevated temperatures. A master film was used as a cast which is hotpressed against the film until the structures are formed on the surface. A commercial prismatic master film with grooves is used as a master. The prism angle is 90° and the depth of the prisms can vary. Pyramids are prepared by performing the embossing twice, the first time to generate grooves, and the second time with the grooves of the second embossing being right-crossed with those of the first to form the pyramids. In Example 1, pyramids having a peak to valley distance of about 28 μm were prepared. A corresponding film having no microstructured surface was manufactured for comparative analysis.

### Measurement of the Efficiency Enhancement

The solar cell photoelectric conversion efficiency was measured by a Newport 300 W full spectrum solar simulator system. The light intensity was adjusted to one sun (AM1.5G) by a 2×2 cm calibrated reference monocrystalline silicon solar cell. Then the I-V characterization of the CdS/CdTe solar cell was performed under the same irradiation and its efficiency is calculated by the Newport software program which is installed in the simulator. After determining the stand alone efficiency of the cell, the efficiency enhancement of the cell with the films is measured. The films were cut to the same shape and size of the light incident active window of the CdS/CdTe cell, and are attached to the light incident front glass substrate of the CdS/CdTe cell using a refractive index matching liquid (n=1.500) fill in between the film and the light incident glass surface of the CdS/CdTe solar cell.

For the single layer wavelength conversion films (e.g., films where microstructured surface and the luminescent dye are combined in one layer, as illustrated in, e.g., FIGS. 2, 5, and 6), the efficiency enhancement is measured first with a plain surface wavelength conversion film having no microstructures and then with a microstructured wavelength conversion film. The plain film and the microstructured film are the same except for the presence of surface structures. For the wavelength conversion films comprising more than one layer (e.g. wavelength conversion films comprising a luminescent medium layer and a microstructured polymer layer, as illustrated in, e.g., FIGS. 3, 4, and 7-11), the efficiency enhancement is measured first with just the luminescent medium layer and then with both the microstructured polymer layer and the luminescent medium layer. The efficiency enhancement of the solar cell with the attached film was determined using the following equation:

Efficiency Enhancement=(η_{cell+film}−η_{cell})η_{cell}*100%

### Example 2

A microstructured wavelength conversion film, which comprises a microstructured polymer layer 101 with a textured top surface, and a luminescent medium layer 102 made of an optically transparent polymer matrix and at least one luminescent dye, is fabricated as two separate thin films, as illustrated in FIG. 3.

First, a plain luminescent medium layer is fabricated by (i) preparing a Polyvinyl butyral (PVB) polymer solution by dissolving a PVB powder (from Aldrich and used as received) in TCE (from Aldrich and used as received) at a predetermined ratio of 20 wt %; (ii) preparing a luminescent dye containing a PVB matrix by mixing the PVB polymer solution with the synthesized Compound 2 at a weight ratio (Compound 2/PVB) of 0.3 wt % to obtain a dye-containing polymer solution; (iii) forming the dye/polymer thin film by directly casting the dye-containing polymer solution onto a glass substrate, then heat treating the substrate from room temperature up to 100° C. in 2 hours, completely removing the remaining solvent by further vacuum heating at 130° C. overnight; and (iv) peeling off the dye/polymer thin film under the water and then drying out the free-standing polymer film before forming the microstructures; (v) the film thickness was 250 μm, which was obtained by varying the dye/polymer solution concentration and evaporation speed.

Then, the microstructured polymer layer is fabricated using the same method as that used to fabricate the luminescent medium layer, except that the luminescent dye is not used. The microstructures are formed on the surface of the microstructured polymer layer similarly to the method described in Example 1. In Example 2, pyramids in the microstructured polymer layer having a peak to valley distance of about of 13 μm were prepared.

### Example 3

A microstructured wavelength conversion film was obtained in the same manner as in Example 2 except that the luminescent dye used was a mixture of Compound 2 (0.3 wt %) and Compound 5 (0.3 wt %).

### Example 4

A microstructured wavelength conversion film was obtained in the same manner as in Example 2 except that the luminescent dye used was a mixture of Compound 2 (0.3 wt %) and Compound 8 (0.3 wt %).

### Example 5

A microstructured wavelength conversion film was obtained in the same manner as in Example 2 except that the solar cell used was a CIGS solar cell instead of a CdS/CdTe solar cell.

### Example 6

A microstructured wavelength conversion film was obtained in the same manner as in Example 5 except that the luminescent dye used was a mixture of Compound 2 (0.3 wt %) and Compound 5 (0.3 wt %).

### Example 7

A microstructured wavelength conversion film was obtained in the same manner as in Example 5 except that the luminescent dye used was a mixture of Compound 2 (0.3 wt %) and Compound 8 (0.3 wt %).

### Example 8

A microstructured wavelength conversion film was obtained in the same manner as in Example 2 except that the microstructures were grooves instead of pyramids, and the peak to valley distance of the grooves was about 28 μm.

### Example 9

A microstructured wavelength conversion film was obtained in the same manner as in Example 2 except that the pyramids had a peak to valley distance of about 28 μm.

### Example 10

A microstructured wavelength conversion film was obtained in the same manner as in Example 2.

### Example 11

A microstructured wavelength conversion film was obtained in the same manner as in Example 2 except that the luminescent dye used was Compound 9.

The efficiency enhancement of the wavelength conversion films comprising a microstructured surface is provided below in Table 1.

TABLE 1
Efficiency enhancement of various plain versus microstructured wavelength
conversion (WLC) films.

| | | | | | | Micro- |
|---|---|---|---|---|---|---|
| | | | | Plain | | structured |
| | | | | WLC | Type of | WLC |
| | | | | Film | Micro- | Film |
| | Polymer | Luminescent | Solar | Efficiency | structured | Efficiency |
| Example | Matrix | Dye | cell | Enhancement | Film | Enhancement |
| 1 | PVB | Compound 2 | CdS/ | 14.3% | Single Layer, | 15.8% |
| | | | CdTe | | Pyramids 28 μm | |
| | | | | | depth | |
| 2 | PVB | Compound 2 | CdS/ | 13.8% | Separate | 16.8% |
| | | | CdTe | | Layers, | |
| | | | | | Pyramids 13 μm | |
| | | | | | depth | |
| 3 | PVB | Mixture of | CdS/ | 15% | Separate | 16.9% |
| | | Compound 2 | CdTe | | Layers, | |
| | | and 5 | | | Pyramids 13 μm | |
| | | | | | depth | |
| 4 | PVB | Mixture of | CdS/ | 14.2% | Separate | 17.1% |
| | | Compound | CdTe | | Layers, | |
| | | 2 and 8 | | | Pyramids 13 μm | |
| | | | | | depth | |
| 5 | PVB | Compound 2 | CIGS | 10.0% | Separate | 11.3% |
| | | | | | Layers, | |
| | | | | | Pyramids 13 μm | |
| | | | | | depth | |
| 6 | PVB | Mixture of | CIGS | 10.2% | Separate | 12.5% |
| | | Compound | | | Layers, | |
| | | 2 and 5 | | | Pyramids 13 μm | |
| | | | | | depth | |
| 7 | PVB | Mixture of | CIGS | 11.6% | Separate | 13.2% |
| | | Compound 2 | | | Layers, | |
| | | and 8 | | | Pyramids 13 μm | |
| | | | | | depth | |
| 8 | PVB | Compound 2 | CdS/ | 14.2% | Separate | 16.0% |
| | | | CdTe | | Layers, | |
| | | | | | Grooves 28 μm | |
| | | | | | depth | |
| 9 | PVB | Compound 2 | CdS/ | 14.2% | Separate | 16.2% |
| | | | CdTe | | Layers, | |
| | | | | | Pyramids 28 μm | |
| | | | | | depth | |
| 10 | PVB | Compound 2 | CdS/ | 14.2% | Separate | 17.2% |
| | | | CdTe | | Layers, | |
| | | | | | Pyramids 13 μm | |
| | | | | | depth | |
| 11 | PVB | Compound 9 | CdS/ | 14.0% | Separate | 17.0% |
| | | | CdTe | | Layers, | |
| | | | | | Pyramids 13 μm | |
| | | | | | depth | |

As illustrated in Table 1, the solar photoelectric conversion efficiency of CdS/CdTe and CIGS solar cells is greatly enhanced by applying the microstructured wavelength conversion film, as disclosed herein, to the solar cell. All prepared examples using the microstructured wavelength conversion film disclosed herein show an improved efficiency enhancement compared to using the wavelength conversion film without the microstructures. The microstructures reduce the loss of photons to the environment, resulting in a larger electrical output of the photovoltaic device. The data also suggests that smaller sized microstructures have even better performance. The further improvement in the photoelectric conversion efficiency of the solar cells by employing the microstructured surface in conjunction with the luminescent medium offers an attractive solution to aid in lowering costs and increasing electrical output of photovoltaic devices.

Although the foregoing description has shown, described, and pointed out the fundamental novel features of the present teachings, it will be understood that various omissions, substitutions, and changes in the form of the detail of the invention as illustrated, as well as the uses thereof, may be made by those skilled in the art, without departing from the scope of the present teachings. Consequently, the scope of the present teachings should not be limited to the foregoing discussion, but should be defined by the appended claims. All patents, patent publications and other documents referred to herein are hereby incorporated by reference in their entirety.

1. A microstructured wavelength conversion film, comprising:
a bottom surface;
a top surface for receiving incident light, wherein the top surface comprises structures configured to increase the amount of photons emitted through the bottom surface; and
a luminescent medium layer comprising a first optically transparent polymer matrix and at least one luminescent dye.

2. The microstructured wavelength conversion film of claim 1, further comprising a microstructured polymer layer over the luminescent medium layer, wherein the microstructured polymer layer comprises a second optically transparent polymer matrix.

3. The microstructured wavelength conversion film of claim 2, wherein the second optically transparent polymer matrix comprises a substance selected from the group consisting of polyethylene terephthalate, polymethyl methacrylate, polyvinyl butyral, ethylene vinyl acetate, ethylene tetrafluoroethylene, polyimide, amorphous polycarbonate, polystyrene, siloxane sol-gel, polyurethane, polyacrylate, and combinations thereof.

4. The microstructured wavelength conversion film of claim 1, wherein the first optically transparent polymer matrix comprises a substance selected from the group consisting of polyethylene terephthalate, polymethyl methacrylate, polyvinyl butyral, ethylene vinyl acetate, ethylene tetrafluoroethylene, polyimide, amorphous polycarbonate, polystyrene, siloxane sol-gel, polyurethane, polyacrylate, and combinations thereof.

5. The microstructured wavelength conversion film of claim 1, wherein the structures are independently selected from the group consisting of grooves, pyramids, prisms, cones, blocks, rings, pillars, and combinations thereof.

6. The microstructured wavelength conversion film of claim 1, wherein the structures have a peak to valley distance ranging from about 0.01 μm to about 100 μm.

7. The microstructured wavelength conversion film of claim 1, wherein the structures have a peak to valley distance ranging from about 1 μm to about 50 μm.

8. The microstructured wavelength conversion film of claim 1, wherein the first transparent polymer matrix comprises a substance selected from the group consisting of polyethylene terephthalate, polymethyl methacrylate, polyvinyl butyral, ethylene vinyl acetate, ethylene tetrafluoroethylene, polyimide, amorphous polycarbonate, polystyrene, siloxane sol-gel, polyurethane, polyacrylate, and combinations thereof.

9. The microstructured wavelength conversion film of claim 1, wherein the refractive index of the first polymer matrix material is in the range of about 1.4 to about 1.7.

10. The microstructured wavelength conversion film of claim 1, wherein the luminescent dye is present in the first polymer matrix of the luminescent medium layer in an amount in the range of about 0.01 wt % to about 3.0 wt %.

11. The microstructured wavelength conversion film of claim 1, wherein the luminescent dye is present in the first polymer matrix of the luminescent medium layer in an amount in the range of about 0.05 wt % to about 1.0 wt %.

12. The microstructured wavelength conversion film of claim 1, wherein the at least one luminescent dye is an organic dye.

13. The microstructured wavelength conversion film of claim 1, wherein the at least one luminescent dye is selected from the group consisting of perylene derivative dyes, benzotriazole derivative dyes, and benzothiadiazole derivative dyes.

14. The microstructured wavelength conversion film of claim 1, wherein at least one luminescent dye is represented by formula (I-a) or (I-b): 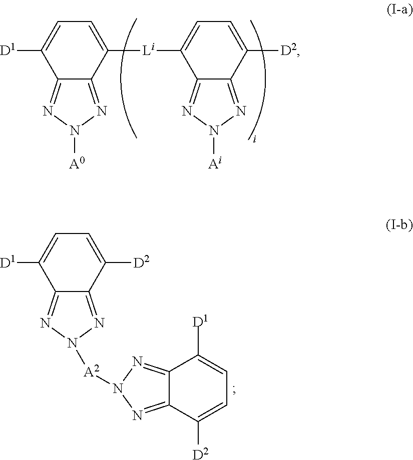
wherein:
i is an integer in the range of 0 to 100;
A⁰ and Aⁱ are each independently selected from the group consisting of optionally substituted alkyl, optionally substituted alkenyl, optionally substituted heteroalkyl, optionally substituted aryl, optionally substituted heteroaryl, optionally substituted amino, optionally substituted amido, optionally substituted cyclic amido, optionally substituted cyclic imido, optionally substituted alkoxy, and optionally substituted carboxy, and optionally substituted carbonyl;
A² is selected from the group consisting of optionally substituted alkylene, optionally substituted alkenylene, optionally substituted arylene, optionally substituted heteroarylene, ketone, ester, and 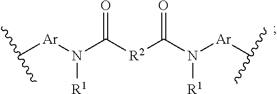
wherein Ar is optionally substituted aryl or optionally substituted heteroaryl; le is selected from the group consisting of H, alkyl, alkenyl, aryl, heteroaryl, aralkyl, and alkaryl; and R² is selected from the group consisting of optionally substituted alkylene, optionally substituted alkenylene, optionally substituted arylene, optionally substituted heteroarylene, ketone, and ester; or le and R² may be connected together to form a ring;
D¹ and D² are each independently selected from the group consisting of hydrogen, optionally substituted alkoxy, optionally substituted aryloxy, optionally substituted acyloxy, optionally substituted alkyl, optionally substituted aryl, optionally substituted heteroaryl, optionally substituted amino, amido, cyclic amido, and cyclic imido, provided that D¹ and D² are not both hydrogen; and
Lⁱ is independently selected from the group consisting of optionally substituted alkylene, optionally substituted alkenylene, optionally substituted alkynylene, optionally substituted arylene, and optionally substituted heteroarylene.

15. The micro structured wavelength conversion film of claim 1, wherein at least one luminescent dye is further represented by formula (II-a) or (II-b): 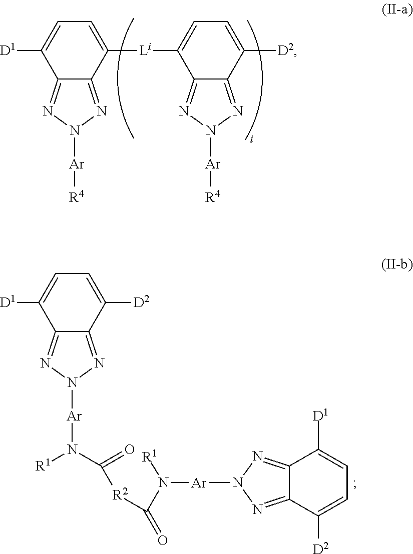
wherein:
i is an integer in the range of 0 to 100;
Ar is optionally substituted aryl or optionally substituted heteroaryl;
R⁴ is 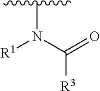
or optionally substituted cyclic imido;
R¹ is each independently selected from the group consisting of H, alkyl, alkenyl, aryl, heteroaryl, aralkyl, and alkaryl;
R³ is each independently selected from the group consisting of optionally substituted alkyl, optionally substituted alkenyl, optionally substituted aryl, and optionally substituted heteroaryl; or R′ and R″ may be connected together to form a ring;
R² is selected from the group consisting of optionally substituted alkylene, optionally substituted alkenylene, optionally substituted arylene, and optionally substituted heteroarylene;
D¹ and D² are each independently selected from the group consisting of hydrogen, optionally substituted alkoxy, optionally substituted aryloxy, optionally substituted acyloxy, optionally substituted alkyl, optionally substituted aryl, optionally substituted heteroaryl, optionally substituted amino, amido, cyclic amido, and cyclic imido, provided that D¹ and D² are not both hydrogen; and
Lⁱ is independently selected from the group consisting of optionally substituted alkylene, optionally substituted alkenylene, optionally substituted alkynylene, optionally substituted arylene, and optionally substituted heteroarylene.

16. The microstructured wavelength conversion film of claim 1, wherein at least one luminescent dye is further represented by formula (III-a) or (III-b): 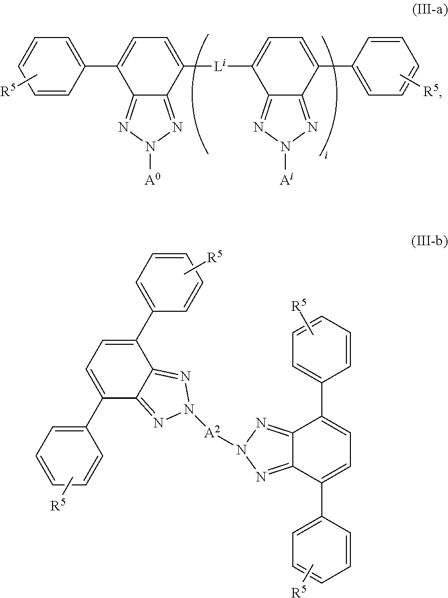
wherein:
i is an integer in the range of 0 to 100;
A⁰ and Aⁱ are each independently selected from the group consisting of optionally substituted alkyl, optionally substituted alkenyl, optionally substituted heteroalkyl, optionally substituted amido, optionally substituted alkoxy, optionally substituted cabonyl, and optionally substituted carboxy;
each R⁵ is independently selected from the group consisting of optionally substituted alkoxy, optionally substituted aryloxy, optionally substituted acyloxy, and amino;
A² is selected from the group consisting of optionally substituted alkylene, optionally substituted alkenylene, optionally substituted arylene, optionally substituted heteroarylene, ketone, ester, and 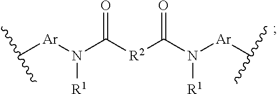
wherein Ar is optionally substituted aryl or optionally substituted heteroaryl; R¹ is selected from the group consisting of H, alkyl, alkenyl, aryl, heteroaryl, aralkyl, and alkaryl; and R² is selected from the group consisting of optionally substituted alkylene, optionally substituted alkenylene, optionally substituted arylene, optionally substituted heteroarylene, ketone, and ester; or le and R² may be connected together to form a ring; and
Lⁱ is independently selected from the group consisting of optionally substituted alkylene, optionally substituted alkenylene, optionally substituted alkynylene, optionally substituted arylene, and optionally substituted heteroarylene.

17. The microstructured wavelength conversion film of claim 1, wherein at least one luminescent dye is represented by formula (IV): 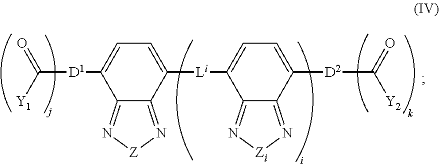
wherein,
i is an integer in the range of 0 to 100;
Z and Zᵢ are each independently selected from the group consisting of —O—, —S—, —Se—, —Te—, —NR⁶—, —CR⁶═CR⁶—, and —CR⁶═N—, wherein R⁶ is hydrogen, optionally substitute C₁-C₆ alkyl, or optionally substituted C₁-C₁₀ aryl; and
D¹ and D² are independently selected from the group consisting of optionally substituted alkoxy, optionally substituted aryloxy, optionally substituted acyloxy, optionally substituted alkyl, optionally substituted aryl, optionally substituted heteroaryl, optionally substituted amino, amido, cyclic amido, and cyclic imido;
j is 0, 1 or 2, and k is 0, 1, or 2;
Y₁ and Y₂ are independently selected from the group consisting of optionally substituted aryl, optionally substituted alkyl, optionally substituted cycloalkyl, optionally substituted alkoxy, and optionally substituted amino; and
Lⁱ is independently selected from the group consisting of optionally substituted alkylene, optionally substituted alkenylene, optionally substituted alkynylene, optionally substituted arylene, and optionally substituted heteroarylene.

18. The microstructured wavelength conversion film of claim 1, wherein at least one luminescent dye is represented by formula (V-a) or formula (V-b): 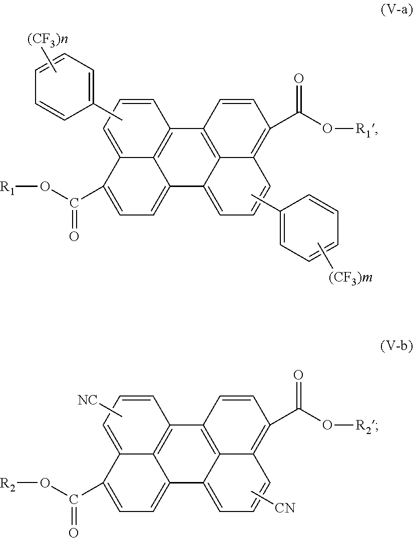
wherein R₁ and R₁′ are each independently selected from the group consisting of hydrogen, C₁-C₁₀ alkyl, C₃-C₁₀ cycloalkyl, C₁-C₁₀ alkoxy, C₆-C₁₈ aryl, and C₆-C₂₀ aralkyl; m and n are each independently 1, 2, 3, 4, or 5; and R₂ and R₂′ are each independently selected from the group consisting of a C₆-C₁₈ aryl and C₆-C₂₀ aralkyl.

19. A solar energy conversion module comprising:
a solar cell, and
a microstructured wavelength conversion film according to claim 1 over the solar cell.

20. The solar energy conversion module of claim 19, further comprising a light incident surface for the solar cell, wherein the light incident surface is between the microstructured wavelength conversion film and the solar cell.

21. The solar energy conversion module of claim 20, further comprising a refractive index matching liquid that is used to attach the microstructured wavelength conversion film to the light incident surface.

22. The solar energy conversion module of claim 19, further comprising a light incident surface for the solar cell, wherein the light incident surface is over the microstructured wavelength conversion film.

23. The solar energy conversion module of claim 19, further comprising a light incident surface for the solar cell, wherein the light incident surface is between the microstructured wavelength conversion film and the luminescent medium layer.

24. The solar energy conversion module of claim 23, further comprising a refractive index matching liquid that is used to attach the luminescent medium layer to the light incident surface.

25. The solar energy conversion module of any claim 19, wherein the microstructured wavelength conversion film has a thickness in the range of about 0.1 μm to about 1 mm.

26. The solar energy conversion module of any claim 19, wherein the microstructured wavelength conversion film has a thickness in the range of about 0.5 μm to about 0.5 mm.

27. The solar energy conversion module of any claim 19, wherein the solar cell is selected from the group consisting of Cadmium Sulfide/Cadmium Telluride solar cell, Copper Indium Gallium Diselenide solar cell, amorphous Silicon solar cell, microcrystalline Silicon solar cell, and crystalline Silicon solar cell.

28. A method for improving the performance of a solar energy conversion device, comprising applying a microstructured wavelength conversion film according to claim 1 onto a light incident surface for a solar cell.

29. A method for improving the performance of a solar energy conversion device, comprising incorporating a microstructured wavelength conversion film according to claim 1 into the solar energy conversion device, such that the luminescent medium layer is between a solar cell and a light incident surface for the solar cell.

30. The method of claim 29, further comprising applying a microstructured wavelength conversion film onto the light incident surface.
